(19) United States
(12) Patent Application Publication
(10) Pub. No.: US 2026/0181893 A1
(43) Pub. Date: Jun. 25, 2026

(54) SEMICONDUCTOR DEVICE

(71) Applicant: Samsung Electronics Co., Ltd., Suwon-si (KR)

(72) Inventors: Hyunji KIM, Suwon-si (KR); Hyeongjin KIM, Suwon-si (KR); Taekkyu YOON, Suwon-si (KR); Jeehoon HAN, Suwon-si (KR)

(73) Assignee: Samsung Electronics Co., Ltd., Suwon-si (KR)

(21) Appl. No.: 19/287,237

(22) Filed: Jul. 31, 2025

(30) Foreign Application Priority Data
Dec. 20, 2024 (KR) 10-2024-0193324

(51) Int. Cl. H10B 43/27; H10B 41/27; H10B 41/35; H10B 41/41; H10B 43/35; H10B 43/40

(52) U.S. Cl. CPC H10B 43/27; H10B 41/27; H10B 41/35; H10B 41/41; H10B 43/35; H10B 43/40

(57) ABSTRACT

A semiconductor device including a peripheral circuit structure; and a cell structure on the peripheral circuit structure and including a cell region and a connection region. The cell structure includes gate electrodes and mold insulating layers alternately arranged on each other in a vertical direction; a channel structure in the cell region, passing through the gate electrodes; a cell plug contacting a selection electrode from among the gate electrodes and passing through non-selection electrodes from among the gate electrodes in the connection region; and insulating spacers on a side surface of the cell plug and spaced apart from each other in the vertical direction. Each of the non-selection electrodes and the selection electrode includes a conductive layer and a coating layer surrounding the conductive layer. The insulating spacers are between the non-selection electrodes and the side surface of the cell plug.

### CROSS-REFERENCE TO RELATED APPLICATION

This application is based on and claims priority under 35 U.S.C. § 119 to Korean Patent Application No. 10-2024-0193324, filed on Dec. 20, 2024, in the Korean Intellectual Property Office, the disclosure of which is incorporated by reference herein in its entirety.

### BACKGROUND

The inventive concepts relate to semiconductor devices, and more particularly to semiconductor devices including a cell plug.

There is a desire to provide semiconductor devices capable of storing high-capacity data in electronic systems requiring data storage. Accordingly, methods for increasing the data storage capacity of semiconductor devices have been studied. For example, as one of the methods for increasing the data storage capacity of semiconductor devices, a semiconductor device including memory cells arranged three-dimensionally, instead of memory cells arranged two-dimensionally, has been proposed.

### SUMMARY

The inventive concepts provide a semiconductor device having improved integration and excellent electrical characteristics.

However, the inventive concepts are not limited, and other inventive concepts that are not mentioned may be clearly understood by those skilled in the art from the following description.

Some example embodiments of the inventive concepts provide a semiconductor device that includes a peripheral circuit structure; and a cell structure on the peripheral circuit structure, the cell structure including a cell region and a connection region. The cell structure includes gate electrodes and mold insulating layers alternately stacked on each other in a vertical direction perpendicular to a top surface of the peripheral circuit structure in the cell region and in the connection region, the gate electrodes including a selection electrode and non-selection electrodes; a channel structure extending in the vertical direction through the gate electrodes in the cell region, a cell plug contacting the selection electrode, the cell plug being in the connection region and passing through the non-selection electrodes, and the non-selection electrodes being at a lower vertical level than the selection electrode, and insulating spacers on a side surface of the cell plug, the insulating spacers being spaced apart from each other in the vertical direction. The non-selection electrodes and the selection electrode include a conductive layer and a coating layer surrounding the conductive layer. The insulating spacers are between the non-selection electrodes and the side surface of the cell plug. A first side surface of the conductive layer of the non-selection electrodes faces the side surface of the cell plug. A first side surface of the coating layer of the non-selection electrodes faces the side surface of the cell plug, and first side surfaces of the insulating spacers contact the first side surface of the conductive layer of the non-selection electrodes and the first side surface of the coating layer of the non-selection electrodes.

Some example embodiments of the inventive concepts further provide a semiconductor device that includes a peripheral circuit structure; and a cell structure on the peripheral circuit structure, the cell structure including a cell region and a connection region. The cell structure includes gate electrodes and mold insulating layers alternately stacked on each other in a vertical direction perpendicular to a top surface of the peripheral circuit structure in the cell region and in the connection region, the gate electrodes including a selection electrode and non-selection electrodes; a channel structure extending in the vertical direction through the gate electrodes in the cell region; a dummy plug extending in the vertical direction through the gate electrodes in the connection region; a cell plug contacting the selection electrode, the cell plug being in the connection region and passing through the non-selection electrodes, the non-selection electrodes being at a higher vertical level than the selection electrode; and insulating spacers on a side surface of the cell plug, the insulating spacers being spaced apart from each other in the vertical direction. The non-selection electrodes and the selection electrode include a conductive layer and a coating layer surrounding the conductive layer. The insulating spacers are between the non-selection electrodes and the side surface of the cell plug. A first side surface of the conductive layer of the non-selection electrodes faces the side surface of the cell plug. A first side surface of the coating layer of the non-selection electrodes faces the side surface of the cell plug, and first side surfaces of the insulating spacers directly contact the first side surface of the conductive layer of the non-selection electrodes and the first side surface of the coating layer of the non-selection electrodes.

Some example embodiments of the inventive concepts still further provide a semiconductor device that includes a peripheral circuit structure; and a cell structure on the peripheral circuit structure, the cell structure including a cell region and a connection region. The cell structure includes gate electrodes and mold insulating layers alternately stacked on each other in a vertical direction perpendicular to a top surface of the peripheral circuit structure in the cell region and in the connection region, the gate electrodes including a selection electrode and non-selection electrodes; a channel structure extending in the vertical direction through the gate electrodes and the mold insulating layers in the cell region; a cell plug contacting the selection electrode, the cell plug being in the connection region and passing through the non-selection electrodes; and insulating spacers on a side surface of the cell plug, the insulating spacers being spaced apart from each other in the vertical direction. The non-selection electrodes and the selection electrode include a conductive layer and a coating layer surrounding the conductive layer. The insulating spacers are between the non-selection electrodes and the side surface of the cell plug. A first side surface of the coating layer of the non-selection electrodes and a first side surface of the conductive layer of the non-selection electrodes facing the side surface of the cell plug directly contact first side surfaces of the insulating spacers. The first side surface of the conductive layer of the non-selection electrodes and the first side surface the coating layer of the non-selection electrodes are coplanar with the first side surfaces of the insulating spacers.

Some example embodiments of the inventive concepts provide a method of manufacturing a semiconductor device that includes providing a peripheral circuit structure; and forming a cell structure on the peripheral circuit structure, the cell structure including a cell region and a connection region. The forming of the cell structure includes forming gate electrodes and mold insulating layers alternately stacked on each other in a vertical direction perpendicular to a top surface of the peripheral circuit structure in the cell region and in the connection region, the gate electrodes including a selection electrode and non-selection electrodes, the selection electrode and the non-selection electrodes including a conductive layer and a coating layer surrounding the conductive layer; forming a channel structure extending in the vertical direction through the gate electrodes in the cell region; forming a cell plug contacting the selection electrode, the cell plug being in the connection region and passing through the non-selection electrodes, and the non-selection electrodes being at a lower vertical level than the selection electrode, a first side surface of the conductive layer of the non-selection electrodes facing the side surface of the cell plug, and a first side surface of the coating layer of the non-selection electrodes facing the side surface of the cell plug; and forming insulating spacers on a side surface of the cell plug, the insulating spacers being spaced apart from each other in the vertical direction and being between the non-selection electrodes and the side surface of the cell plug, and first side surfaces of the insulating spacers contacting the first side surface of the conductive layer of the non-selection electrodes and the first side surface of the coating layer of the non-selection electrodes.

Some example embodiments of the method of manufacturing the semiconductor device include forming the first side surface of the conductive layer of the non-selection electrodes and the first side surface of the coating layer of the non-selection electrodes as aligned in the vertical direction and connected to each other.

In some example embodiments of the method of manufacturing the semiconductor device, the first side surface of the conductive layer of the non-selection electrodes is formed as an inwardly concave curved surface.

Some example embodiments of the method of manufacturing the semiconductor device include forming the first side surface of the conductive layer of the non-selection electrodes and the first side surface of the coating layer of the non-selection electrodes as inclined, and an inclination of the first side surface of the conductive layer of the non-selection electrodes is different from an inclination of the first side surface of the coating layer of the non-selection electrodes.

Some example embodiments of the method of manufacturing the semiconductor device include forming second side surfaces of the insulating spacers opposite to the first side surfaces of the insulating spacers as contacting the side surface of the cell plug, the insulating spacers including a first insulating spacer, and the non-selection electrodes including a first non-selection electrode contacting the first insulating spacer, and a separation distance between a first side surface of a conductive layer of the first non-selection electrode and the side surface of the cell plug is less than a separation distance between a first side surface of a coating layer of the first non-selection electrode and the side surface of the cell plug.

Some example embodiments of the method of manufacturing the semiconductor device include forming second side surfaces of the insulating spacers opposite to the first side surfaces of the insulating spacers as contacting the side surface of the cell plug, the insulating spacers including a first insulating spacer, and the non-selection electrodes including a first non-selection electrode contacting the first insulating spacer, and a separation distance between a first side surface of a conductive layer of the first non-selection electrode and the side surface of the cell plug is greater than a separation distance between a side surface of a coating layer of the first non-selection electrode and the side surface of the cell plug.

In some example embodiments of the method of manufacturing the semiconductor device, the cell plug contacts the conductive layer of the selection electrode, and the coating layer of the selection electrode contacts a part of the side surface of the cell plug.

In some example embodiments of the method of manufacturing the semiconductor device, the insulating spacers include a first insulating spacer, and the non-selection electrodes include a first non-selection electrode contacting the first insulating spacer, and a first side surface of the first insulating spacer is coplanar with a first side surface of a conductive layer of the first non-selection electrode and a first side surface of a coating layer of the first non-selection electrode.

In some example embodiments of the method of manufacturing the semiconductor device, the insulating spacers include a first insulating spacer, and the non-selection electrodes include a first non-selection electrode contacting the first insulating spacer, and a first side surface of the first insulating spacer is coplanar with a first side surface of a conductive layer of the first non-selection electrode and a first side surface of a coating layer of the first non-selection electrode.

Some example embodiments of the inventive concepts further provide a method of manufacturing a semiconductor device that includes providing a peripheral circuit structure; and a cell structure on the peripheral circuit structure, the cell structure including a cell region and a connection region. The forming of the cell structure includes forming gate electrodes and mold insulating layers alternately stacked on each other in a vertical direction perpendicular to a top surface of the peripheral circuit structure in the cell region and in the connection region, the gate electrodes including a selection electrode and non-selection electrodes, and the non-selection electrodes and the selection electrode including a conductive layer and a coating layer surrounding the conductive layer; forming a channel structure extending in the vertical direction through the gate electrodes in the cell region; forming a dummy plug extending in the vertical direction through the gate electrodes in the connection region, the dummy plug including protrusions that protrude in a horizontal direction from a side surface of the dummy plug toward the gate electrodes, the protrusions being spaced apart from each other in the vertical direction; forming a cell plug contacting the selection electrode, the cell plug being in the connection region and passing through the non-selection electrodes, the non-selection electrodes being at a higher vertical level than the selection electrode, a first side surface of the conductive layer of the non-selection electrodes facing the side surface of the cell plug, and a first side surface of the coating layer of the non-selection electrodes facing the side surface of the cell plug; and forming insulating spacers on a side surface of the cell plug, the insulating spacers being spaced apart from each other in the vertical direction, the insulating spacers being between the non-selection electrodes and the side surface of the cell plug, and first side surfaces of the insulating spacers directly contacting the first side surface of the conductive layer of the non-selection electrodes and the first side surface of the coating layer of the non-selection electrodes.

Some example embodiments of the inventive concepts further provide a method of manufacturing a semiconductor device that includes providing a peripheral circuit substrate; and forming a cell structure on the peripheral circuit structure, the cell structure including a cell region and a connection region. The forming of the cell structure includes forming a mold stack on a cell substrate, the mold stack including sacrificial layers and mold insulating layers alternatively stacked on each other over the cell substrate; forming a channel structure in the cell region, the channel structure extending through the mold stack in a vertical direction to the cell substrate; forming a dummy plug hole in the connecting region, the dummy plug hole extending through the mold stack to the cell substrate in the vertical direction; forming a cell plug hole in the connection region, the cell plug hole penetrating into the mold stack in the vertical direction; removing side portions of the sacrificial layers between the mold insulating layers through the dummy plug hole to provide dummy recess regions in the dummy plug hole; forming a dummy plug in the dummy plug hole, the dummy plug including protrusions extending into the dummy recess regions; after the forming of the dummy plug, removing the sacrificial layers from between the mold insulating layers of the mold stack; after the removing of the sacrificial layers, forming gate electrodes in spaces between the mold insulating layers; and after the forming of the gate electrodes, forming a cell plug in the cell plug hole.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some example embodiments;

FIG. 2 is an equivalent circuit diagram of a memory cell array of a semiconductor device, according to some example embodiments;

FIG. 3 is a perspective view of a representative configuration of a semiconductor device, according to some example embodiments;

FIG. 4 is a plan view of the semiconductor device of FIG. 3;

FIG. 5 is a schematic cross-sectional view of the semiconductor device of FIG. 4 taken along line A-A′ in FIG. 4;

FIG. 6 is a schematic enlarged view of portion DX1 and portion CX1 in FIG. 5;

FIG. 7 is a schematic enlarged view of portion CX2 of the semiconductor device in FIG. 6;

FIGS. 8, 9, 10 and 11 are schematic enlarged views of a portion of a semiconductor device, according to some example embodiments, wherein for example, FIGS. 8 to 11 are enlarged views corresponding to portion CX2 in FIG. 6;

FIG. 12 is a schematic enlarged view of a portion of a semiconductor device according to some example embodiments, wherein for example, FIG. 12 is an enlarged view corresponding to portion DX2 in FIG. 6;

FIG. 13 is a schematic cross-sectional view of a portion of a semiconductor device according to some example embodiments; and

FIGS. 14, 15, 16, 17, 18A, 18B, 19, 20A, 20B, 21A, 21B, 22A, 22B, 23A, 23B, 24, 25, 26, 27, 28 and 29 are cross-sectional views illustrating a method of manufacturing a semiconductor device according to some example embodiments, wherein for example, FIGS. 14 to 17, 18A, 19, 20A, 21A, 22A, 23A, and 24 to 29 are cross-sectional views corresponding to a cross-section taken along line A-A′ in FIG. 4, FIG. 18B is an enlarged view of portion DX and portion CX in FIG. 18A, and FIGS. 20B, 21B, 22B, and 23B are enlarged views of portion CX in FIGS. 20A, 21A, 22A, and 23A.

### DETAILED DESCRIPTION

Some example embodiments are provided to more fully describe the inventive concepts to those skilled in the art. The some example embodiments may be modified in various other forms, and the scope of the inventive concepts is not limited to the following described some example embodiments. Rather, the following described some example embodiments are provided so that the inventive concepts may be thoroughly, completely and fully understood and conveyed with respect to the spirit of the inventive concepts to those skilled in the art.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

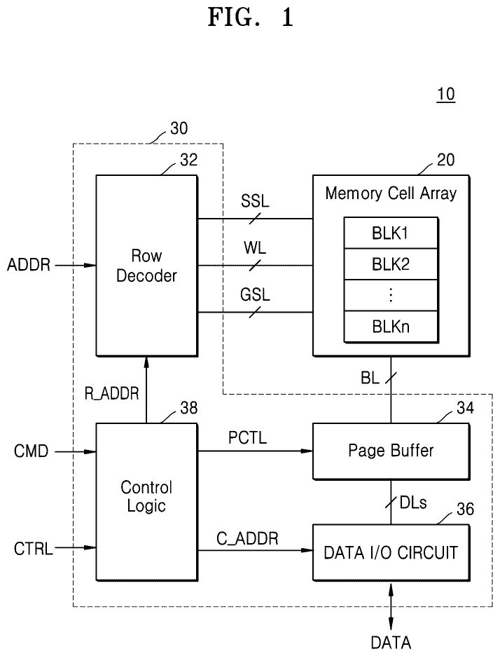

FIG. 1 is a block diagram of a semiconductor device 10 according to some example embodiments.

Referring to FIG. 1, the semiconductor device 10 may include a memory cell array 20 and a peripheral circuit 30. The memory cell array 20 includes a plurality of memory cell blocks BLK1, BLK2, . . . , and BLKn. The plurality of memory cell blocks BLK1, BLK2, . . . , and BLKn may each include a plurality of memory cells. The memory cell blocks BLK1, BLK2, . . . , and BLKn may be connected to the peripheral circuit 30 through a bit line BL, a word line WL, a string selection line SSL, and a ground selection line GSL.

The peripheral circuit 30 may include a row decoder 32, a page buffer 34, a data input/output circuit 36, and a control logic 38 (e.g., a control logic circuit). Although not shown in FIG. 1, the peripheral circuit 30 may further include an input/output interface, a column logic circuit, a voltage generator, a pre-decoder, a temperature sensor, a command decoder, an address decoder, an amplification circuit, and the like.

The memory cell array 20 may be connected to the page buffer 34 via the bit line BL and may be connected to the row decoder 32 via the word line WL, the string selection line SSL, and the ground selection line GSL. In the memory cell array 20, the plurality of memory cells included in the plurality of memory cell blocks BLK1, BLK2, . . . and BLKn may each include a flash memory cell. The memory cell array 20 may include a three-dimensional memory cell array. The three-dimensional memory cell array may include a plurality of NAND strings, wherein each NAND string may include a plurality of memory cells connected to a plurality of word lines WL vertically stacked on a substrate.

The peripheral circuit 30 may receive an address ADDR, a command CMD, and a control signal CTRL from the outside of the semiconductor device 10 and may transmit and receive data DATA to and from a device outside the semiconductor device 10.

The row decoder 32 may select at least one of the plurality of memory cell blocks BLK1, BLK2, . . . , and BLKn in response to the address ADDR from the outside and may select the word line WL, the string selection line SSL, and the ground selection line GSL of the selected memory cell block. The row decoder 32 may pass a voltage to the word line WL of the selected memory cell block to perform a memory operation.

The page buffer 34 may be connected to the memory cell array 20 via the bit line BL. The page buffer 34 may operate as a write driver during a program operation to apply a voltage to the bit line BL in accordance with the data DATA to be stored in the memory cell array 20 and may operate as a sense amplifier during a read operation to sense the data DATA stored in the memory cell array 20. The page buffer 34 may operate in accordance with a control signal PCTL provided from the control logic 38.

The data input/output circuit 36 may be connected to the page buffer 34 via data lines DL. The data input/output circuit 36 may receive the data DATA from a memory controller (not shown) during the program operation and provide the programmed data DATA to the page buffer 34 based on a column address C_ADDR provided from the control logic 38. The data input/output circuit 36 may provide the read data DATA stored in the page buffer 34 to the memory controller based on the column address C_ADDR provided from the control logic 38 during the read operation.

The data input/output circuit 36 may pass an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and the column address C_ADDR to the data input/output circuit 36. The control logic 38 may generate various internal control signals used within the semiconductor device 10 in response to the control signal CTRL. For example, the control logic 38 may adjust the voltage level provided to the word line WL and the bit line BL when performing the memory operation, such as the program operation or an erase operation.

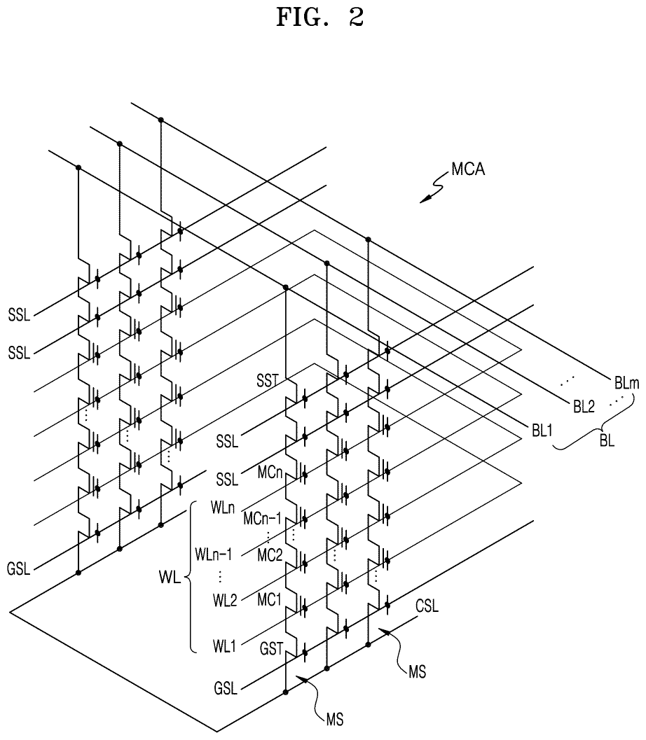

FIG. 2 is an equivalent circuit diagram of a memory cell array of the semiconductor device 10, according to some example embodiments.

Referring to FIG. 2, a memory cell array MCA may include a plurality of memory cell strings MS. The memory cell array MCA may include a plurality of bit lines BL (BL1, BL2, . . . , and BLm), a plurality of word lines WL (WL1, WL2, . . . , WLn−1, and WLn), at least one string selection line SSL, at least one ground selection line GSL, and a common source line CSL. The plurality of memory cell strings MS may be formed between the plurality of bit lines BL (BL1, BL2, . . . , and BLm) and the common source line CSL. FIG. 2 illustrates a some example embodiments where the plurality of memory cell strings MS each include two string selection lines SSL, but the inventive concepts are not limited thereto. For example, the plurality of memory cell strings MS may each include one string selection line SSL.

The plurality of memory cell strings MS may each include a string selection transistor SST, a ground selection transistor GST, and a plurality of memory cell transistors MC1, MC2, . . . , MCn−1, and MCn. A drain region of the string selection transistor SST may be connected to the bit lines BL (BL1, BL2, . . . , and BLm), and a source region of the ground selection transistor GST may be connected to the common source line CSL. The common source line CSL may include a region to which the source regions of the plurality of ground selection transistors GST are commonly connected.

The string selection transistor SST may be connected to the string selection line SSL, and the ground selection transistor GST may be coupled to the ground selection line GSL. The plurality of memory cell transistors MC1, MC2, . . . , MCn−1, and MCn may be connected to the plurality of word lines WL (WL1, WL2, . . . , WLn−1, and WLn), respectively.

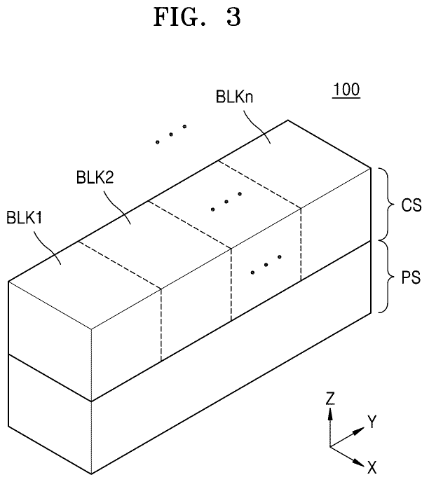

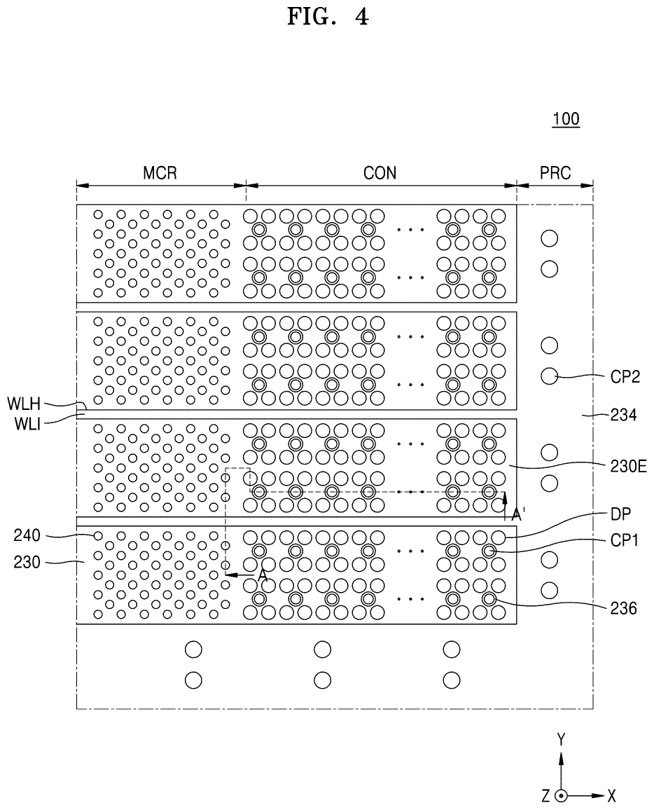

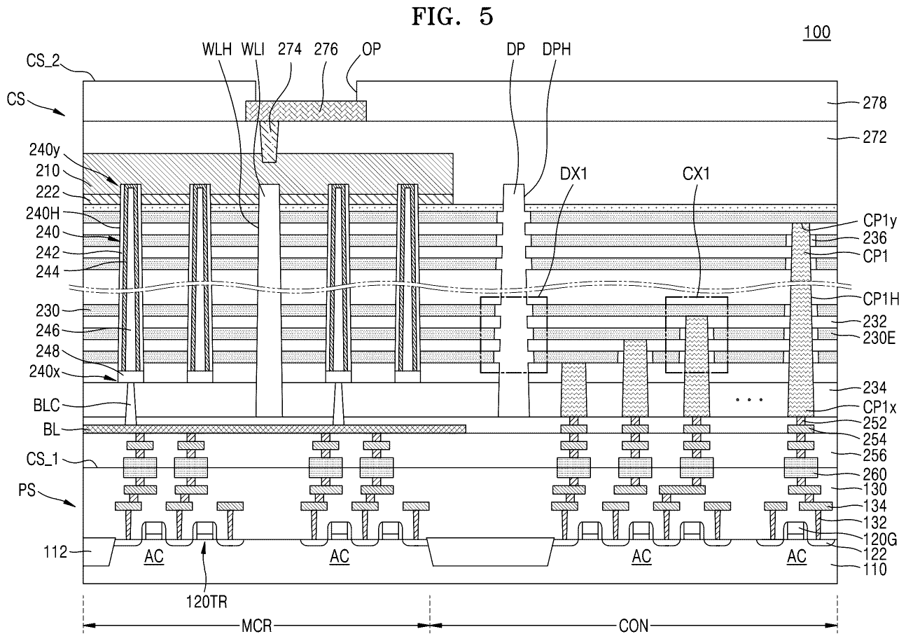

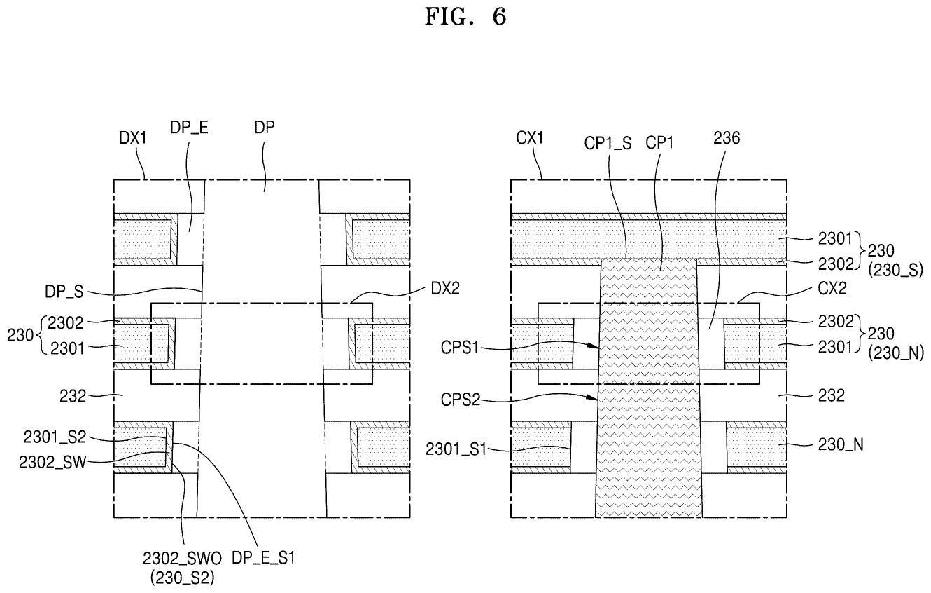

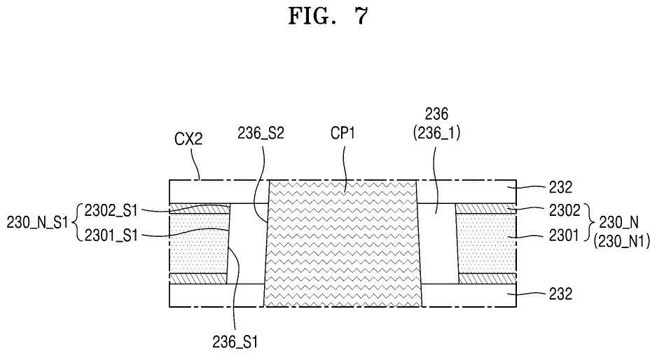

FIG. 3 is a perspective view of a representative configuration of a semiconductor device 100, according to some example embodiments. FIG. 4 is a plan view of the semiconductor device 100 of FIG. 3. FIG. 5 is a schematic cross-sectional view of the semiconductor device 100 of FIG. 4 taken along line A-A′ in FIG. 4. FIG. 6 is a schematic enlarged view of portion DX1 and portion CX1 in FIG. 5. FIG. 7 is a schematic enlarged view of portion CX2 of the semiconductor device 100 in FIG. 6.

Referring to FIGS. 3 to 7, the semiconductor device 100 includes a cell structure CS and a peripheral circuit structure PS that overlap with each other in a vertical direction Z. The cell structure CS may include the memory cell array 20 described with reference to FIG. 1, and the peripheral circuit structure PS may include the peripheral circuit 30 described with reference to FIG. 1.

The cell structure CS may include the plurality of memory cell blocks BLK1, BLK2, . . . , and BLKn. The plurality of memory cell blocks BLK1, BLK2, . . . , and BLKn may each include three-dimensionally arranged memory cells.

The peripheral circuit structure PS may include a peripheral circuit transistor 120TR disposed on a substrate 110. An active region AC may be defined by a device isolation film 112 on the substrate 110, and a plurality of peripheral circuit transistors 120TR may be formed on the active region AC. The plurality of peripheral circuit transistors 120TR may include a peripheral circuit gate 120G and a source/drain region 122 disposed on parts of the substrate 110 on both sides of the peripheral circuit gate 120G.

The substrate 110 may include a semiconductor material, for example, a group IV semiconductor, a group III-V compound semiconductor, or a group II-VI oxide semiconductor. For example, the group IV semiconductor may include silicon (Si), germanium (Ge), or silicon-germanium (SiGe). The substrate 110 may be provided as a bulk wafer or an epitaxial layer. In some example embodiments, the substrate 110 may include a silicon-on-insulator (SOI) substrate, or a germanium-on-insulator (GeOI) substrate.

A plurality of peripheral circuit contacts 132 and a plurality of peripheral circuit wiring layers 134 may be disposed on a top surface of the substrate 110. An interlayer insulating film 130 covering the peripheral circuit transistor 120TR, the plurality of peripheral circuit contacts 132, and the plurality of peripheral circuit wiring layers 134 may be disposed on the substrate 110. The plurality of peripheral circuit wiring layers 134 may have a multilayer structure including a plurality of metal layers arranged at different vertical levels. A connection pad 260 may be disposed on the interlayer insulating film 130, and the peripheral circuit structure PS and the cell structure CS may be electrically connected and bonded to each other by the connection pad 260.

The cell structure CS may include a cell region MCR, a connection region CON, and a peripheral circuit connection region PRC.

The cell region MCR may include a region in which a memory cell block BLK including a plurality of memory cell strings extending in the vertical direction Z is arranged. A common source layer 210, gate electrodes 230, and a channel structure 240 extending through the gate electrodes 230 in the vertical direction Z and connected to the common source layer 210 may be arranged in the cell region MCR.

A plurality of gate extensions 230E connected to the gate electrodes 230, a plurality of cell plugs CP1 electrically connected to the plurality of gate extensions 230E, and a plurality of dummy plugs DP may be arranged in the connection region CON.

A peripheral plug CP2 extending in the vertical direction Z and electrically connected to the peripheral circuit wiring layer 134 may be arranged in the peripheral circuit connection region PRC.

The cell structure CS may include a first side surface CS_1 connected to the peripheral circuit structure PS and a second side surface CS_2 opposite the first side surface CS_1. The drawing illustrates that the first side surface CS_1 of the cell structure CS is arranged below the cell structure CS, and the second side surface CS_2 of the cell structure CS is arranged above the cell structure CS.

Here, for the sake of convenience, as indicated in the drawing, arrangement to be close to the first side surface CS_1 of the cell structure CS is referred to as arrangement at a lower vertical level, and arrangement to be close to the second side surface CS_2 of the cell structure CS is referred to as arrangement at a higher vertical level.

The gate electrodes 230 may be spaced apart from each other in the vertical direction Z in the cell region MCR, and the gate electrodes 230 may be alternately arranged with mold insulating layers 232. The gate electrodes 230 may extend to the connection region CON, and parts of the gate electrodes 230 arranged in the connection region CON may be referred to as the gate extensions 230E. The gate extensions 230E spaced apart from each other in the vertical direction Z may have the same width in a first horizontal direction X. For example, side surfaces of the gate electrodes 230 may be aligned in the vertical direction Z.

In some example embodiments, the gate electrodes 230 may correspond to ground selection lines GSL1 to GSL3, word lines WL1 to WL8, and at least one string selection line SSL1 to SSL3 that constitute memory cell strings MCS11 to MCS33 (see FIG. 2). For example, the uppermost gate electrode 230 may function as the ground selection lines GSL1 to GSL3, the two lowermost gate electrodes 230 may function as the string selection lines SSL1 to SSL3, and the other gate electrodes 230 may function as the word lines WL1 to WL8. Accordingly, the memory cell strings MCS11 to MCS33, in which the ground selection transistor GST, the string selection transistor SST, and the memory cell transistors MCT1 to MCT8 therebetween are connected in series, may be provided. In some example embodiments, at least one of the gate electrodes 230 may function as a dummy word line but is not limited thereto.

A stack isolation insulating layer WLI may be arranged in a stack isolation opening WLH extending in the vertical direction Z through the gate electrodes 230 and the mold insulating layers 232. The stack isolation insulating layer WLI may have a top surface arranged at a higher vertical level than the uppermost gate electrode 230 and may protrude upward from the uppermost gate electrode 230. In some example embodiments, the gate electrodes 230 between a pair of stack isolation openings WLH may constitute one block.

The channel structure 240 may be arranged in a channel hole 240H extending in the vertical direction Z through the gate electrodes 230 and the mold insulating layers 232. The channel structure 240 may include a gate insulating layer 242, a channel layer 244, a buried insulating layer 246, and a drain region 248. The gate insulating layer 242, the channel layer 244, and the buried insulating layer 246 may be sequentially disposed on an inner wall of the channel hole 240H.

The channel structure 240 may include a first end 240x close to the peripheral circuit structure PS and a second end 240y opposite to the first end 240x. In some example embodiments, the channel structure 240 may have an inclined side surface such that the width of the first end 240x is greater than the width of the second end 240y.

The drain region 248 electrically connected to the channel layer 244 may be arranged at the first end 240x of the channel structure 240. The drain region 248 may be connected to a bit line contact BLC, and the channel layer 244 may be electrically connected to the bit line BL through the drain region 248 and the bit line contact BLC. At the second end 240y of the channel structure 240, the top surface of the channel layer 244 may not be covered by the gate insulating layer 242 and the common source layer 210 may be connected to the top surface of the channel layer 244.

In some example embodiments, the gate insulating layer 242 may have a structure including a tunneling dielectric film, a charge storage film, and a blocking dielectric film sequentially arranged on the outer surface of the channel layer 244. The charge storage film may include silicon nitride, boron nitride, silicon boron nitride, or impurity-doped polysilicon, as a region where electrons that have passed through the tunneling dielectric film from the channel layer 244 can be stored.

In some example embodiments, the charge storage film may include a ferroelectric dielectric material. The charge storage film in some example embodiments may include a metal oxide having ferroelectric material properties. For example, the charge storage film may include a ferroelectric material capable of storing data by hysteresis behavior by a voltage applied to the charge storage film. In some example embodiments, the charge storage film may include at least one of hafnium oxide, zirconium oxide, and hafnium zirconium oxide.

An etch stop layer 222 may be disposed on the uppermost gate electrode 230, and the etch stop layer 222 may include polysilicon. In some example embodiments, the etch stop layer 222 may be omitted.

The common source layer 210 may be conformally formed on the etch stop layer 222 to be connected to the second end 240y of the channel structure 240 and cover the top surface of the stack isolation insulating layer WLI. In a plan view, the common source layer 210 may be disposed over the entire area of the cell region MCR.

In some example embodiments, the common source layer 210 may include at least one of Si, Ge, SiGe, gallium arsenide (GaAs), indium gallium arsenide (InGaAs), aluminum gallium arsenide (AlGaAs), and a mixture thereof. In addition, the common source layer 210 may include a semiconductor doped with an n-type impurity. In addition, the common source layer 210 may have a crystal structure including at least one selected from a single crystal, an amorphous structure, and a polycrystalline. In some example embodiments, the common source layer 210 may include polysilicon doped with an n-type impurity.

Between a stack cover insulating layer 234 and the peripheral circuit structure PS, a connection via 252, a connection wiring layer 254, and an interlayer insulating film 256 surrounding the connection via 252 and the connection wiring layer 254 may be arranged. The connection via 252 and the connection wiring layer 254 may be formed in multiple layers to be arranged at different vertical levels and may electrically connect the bit line BL, the cell plug CP1, and the peripheral plug CP2 to the peripheral circuit structure PS through the connection pad 260.

The gate electrodes 230 may extend in a horizontal direction in the cell region MCR and the connection region CON. The gate electrodes 230 disposed in the connection region CON are referred to as gate extensions 230E. The gate extensions 230E may overlap each other in the vertical direction Z in the connection region CON. For example, the gate extensions 230E arranged at different vertical levels in the connection region CON may have the same width in the horizontal direction.

In some example embodiments, each of the gate electrodes 230 may include a conductive layer 2301 and a coating layer 2302 surrounding the conductive layer 2301. The coating layer 2302 may be conformally formed on a surface of the conductive layer 2301 of the gate electrode 230. For example, the coating layer 2302 may include an upper wall formed on a top surface of the conductive layer 2301, a lower wall formed on a bottom surface of the conductive layer, and a sidewall 2302_SW connecting the upper wall to the lower wall of the coating layer 2302. For example, when a part of the coating layer 2302 of the gate electrode 230 is removed, a part of the conductive layer 2301 of the gate electrode 230 may be exposed to the outside through the removed part.

In some example embodiments, the conductive layer 2301 of the gate electrode 230 may include a metal, such as tungsten, nickel, cobalt, or tantalum, a metal silicide, such as tungsten silicide, nickel silicide, cobalt silicide, or tantalum silicide, doped polysilicon, or a combination thereof. In some example embodiments, the coating layer 2302 of the gate electrode 230 may include an insulating material, such as aluminum oxide (AlO), silicon oxide (SiO), or titanium oxide (TiO).

The plurality of cell plugs CP1 may extend in the vertical direction Z through the stack cover insulating layer 234, the mold insulating layers 232, and the gate extensions 230E in the connection region CON. The plurality of cell plugs CP1 may have different heights in the vertical direction Z. For example, each of the plurality of cell plugs CP1 may have a different height depending on the gate electrode 230 to which the cell plug CP1 is connected. For example, the number of gate electrodes 230 through which the cell plug CP1 passes through may be different.

The cell plug CP1 may have a plurality of first side portions CPS1 and a plurality of second side portions CPS2 arranged alternately with each other. The plurality of first side portions CPS1 may be in contact with second side surfaces 236_S2 of a plurality of insulating spacers 236, and the plurality of second side portions CPS2 may be in contact with side surfaces of the mold insulating layers 232. The side surfaces of the mold insulating layers 232 and the second side surfaces 236_S2 of the plurality of insulating spacers 236 may be vertically aligned and continuously connected to each other, so that the side surface of the cell plug CP1 may also have a substantially vertically extending profile.

In some example embodiments, the cell plug CP1 may include a first end CP1x and a second end CP1y. The first ends CP1x of the plurality of cell plugs CP1 may all be arranged at the same vertical level and may also be arranged at the same vertical level as the top surface of the stack cover insulating layer 234. The second ends CP1y of the plurality of cell plugs CP1 may be arranged at different vertical levels. For example, the second ends CP1y of the plurality of cell plugs CP1 may be located on the gate electrodes 230 having different vertical levels.

The gate electrode 230 may include a selection electrode 230_S and non-selection electrodes 230_N. The cell plug CP1 may be in contact with one of the gate electrodes 230. For example, the selection electrode 230_S may include the gate electrode 230 in contact with one cell plug CP1. For example, the gate electrode 230 in contact with the one cell plug CP1 may be referred to as the gate electrode 230 corresponding to the one cell plug CP1.

For example, the one cell plug CP1 may be in contact with the conductive layer 2301 of the selection electrode 230_S to be electrically connected to the selection electrode 230_S. One surface CP1_S of the one cell plug CP1 may be in contact with the conductive layer 2301 of the selection electrode 230_S, and a side surface of the one cell plug CP1 may be in contact with the coating layer 2302 of the selection electrode 230_S.

The non-selection electrodes 230_N may include the gate electrodes 230 located below the selection electrode 230_S among the gate electrodes 230. For example, the non-selection electrodes 230_N may include the gate electrodes 230 located between the stack cover insulating layer 234 and the selection electrode 230_S among the gate electrodes 230. For example, the one cell plug CP1 may extend in the vertical direction Z from the stack cover insulating layer 234 to the selection electrode 230_S through the non-selection electrodes 230_N and the mold insulating layers 232.

In some example embodiments, the plurality of cell plugs CP1 may include a metal, such as tungsten, nickel, cobalt, or tantalum, a metal silicide, such as tungsten silicide, nickel silicide, cobalt silicide, or tantalum silicide, doped polysilicon, or a combination thereof.

The insulating spacer 236 may be located on a side surface of the cell plug CP1. For example, the side surface of the cell plug CP1 may be surrounded by the insulating spacers 236.

In some example embodiments, the insulating spacers 236 located on the side surface of the one cell plug CP1 may be spaced apart from each other in the vertical direction Z. For example, the insulating spacers 236 may be spaced apart from each other in the vertical direction Z with the mold insulating layers 232 in between. Each of the insulating spacers 236 may be located between the one cell plug CP1 and the gate electrode 230. For example, the insulating spacer 236 may be between the one cell plug CP1 and the non-selection electrode 230_N.

In some example embodiments, the one surface CP1_S, e.g., a top surface, of the one cell plug CP1 may be electrically connected to the selection electrode 230_S, while the side surface of the one cell plug CP1 may not be electrically connected to the non-selection electrode 230_N arranged at a lower vertical level than the selection electrode 230_S.

The insulating spacer 236 may be positioned between the non-selection electrode 230_N arranged at a lower vertical level than the selection electrode 230_S and the side surface of the one cell plug CP1. Thus, the non-selection electrodes 230_N and the side surface of the one cell plug CP1 may be insulated from each other.

In some example embodiments, the insulating spacers 236 may have a ring-shaped horizontal cross-section. For example, the second side surface 236_S2 of the insulating spacer 236 may include an inner surface in contact with the cell plug CP1, and the first side surface 236_S1 of the insulating spacer 236 may include an outer surface opposing the second side surface 236_S2 of the insulating spacer 236. The thickness of the insulating spacer 236 in the horizontal direction, that is, the separation distance between the first side surface 236_S1 and the second side surface 236_S2 of the insulating spacer 236 may be in a range from about 10 Å to about 100 Å.

As shown in FIG. 6, the top surface of the insulating spacer 236 may be arranged at the same level as the top surface of the non-selection electrode 230_N facing the insulating spacer 236, and the bottom surface of the insulating spacer 236 may be arranged at the same level as the bottom surface of the non-selection electrode 230_N facing the insulating spacer 236. The height of the insulating spacer 236 in the vertical direction Z may be the same as the height of the non-selection electrode 230_N in vertical direction Z. For example, the height of the insulating spacer 236 in the vertical direction Z may be greater than the height of the conductive layer 2301 of the non-selection electrode 230_N in the vertical direction Z.

In some example embodiments, the insulating spacers 236 may include silicon oxide. In some example embodiments, the insulating spacers 236 may include silicon oxide containing a small amount (e.g., 5 atomic percent (at %) or less) of any one element of chlorine, fluorine, and bromine.

The non-selection electrode 230_N may include a first side surface 230_N_S1. The first side surface 230_N_S1 of the non-selection electrode 230_N may face the side surface of the one cell plug CP1. For example, while the one cell plug CP1 passes through the non-selection electrodes 230_N, a side surface defining a hole formed in the non-selection electrode 230_N may include the first side surface 230_N_S1 of the non-selection electrode 230_N.

The first side surface of the non-selection electrode 230_N may include a first side surface 2301_S1 of the conductive layer 2301 and a first side surface 2302_S1 of the coating layer 2302 of the non-selection electrode 230_N. For example, the first side surface 2301_S1 of the conductive layer 2301 of the non-selection electrode 230_N may face the cell plug CP1, and the first side surface 2302_S1 of the coating layer 2302 may face the cell plug CP1.

The first side surface 236_S1 of the insulating spacer 236 may be in contact with the first side surface 2301_S1 of the conductive layer 2301 of the non-selection electrode 230_N and may be in contact with the first side surface 2302_S1 of the coating layer 2302 of the non-selection electrode 230_N.

The non-selection electrodes 230_N and the insulating spacers 236 are for example described with reference to FIG. 7. For convenience of description, the description is made with reference to a first non-selection electrode 230_N1 and a first insulating spacer 236_1 that are in contact with each other, among the non-selection electrodes 230_N and the insulating spacers 236.

The first side surface 2301_S1 of the conductive layer 2301 of the first non-selection electrode 230_N1 may not be covered by the coating layer 2302 of the first non-selection electrode 230_N1 and may be in direct contact with the first insulating spacer 236_1. For example, the first side surface 2301_S1 of the conductive layer 2301 of the first non-selection electrode 230_N1 may be completely covered by the first insulating spacer 236_1. For example, as forming of the insulating spacers 236 is performed after forming the gate electrodes 230, the first side surface 2301_S1 of the conductive layer 2301 of the first non-selection electrode 230_N1 may be exposed to the outside of the first non-selection electrode 230_N1 to be in contact with the first insulating spacer 236_1.

The first side surface 236_S1 of the first insulating spacer 236_1 may be coplanar with the first side surface 2301_S1 of the conductive layer 2301 of the first non-selection electrode 230_N1 and with the first side surface 2302_S1 of the coating layer 2302 of the first non-selection electrode 230_N1. For example, after the conductive layer 2301 of the first non-selection electrode 230_N1 and the coating layer 2302 of the first non-selection electrode 230_N1 are partially etched, the first insulating spacer 236_1 may be formed, so that the first side surface 236_S1 of the first insulating spacer 236_1 is coplanar with the first side surface 2301_S1 of the conductive layer 2301 of the first non-selection electrode 230_N1 and with the first side surface 2302_S1 of the coating layer 2302 of the first non-selection electrode 230_N1.

The first side surface 2301_S1 of the conductive layer 2301 of the first non-selection electrode 230_N1 and the first side surface 2302_S1 of the coating layer 2302 of the first non-selection electrode 230_N1 may be aligned in the vertical direction Z and continuously connected to each other. For example, each of the first side surface 2301_S1 of the conductive layer 2301 of the first non-selection electrode 230_N1 and the first side surface 2302_S1 of the coating layer 2302 of the first non-selection electrode 230_N1 may be inclined.

In some example embodiments, the inclination of the first side surface 2301_S1 of the conductive layer 2301 of the non-selection electrode 230_N may be the same as the inclination of the first side surface 2302_S1 of the coating layer 2302 of the non-selection electrode 230_N. For example, the first side surface 2301_S1 of the conductive layer 2301 of the first non-selection electrode 230_N1 and the first side surface 2302_S1 of the coating layer 2302 of the first non-selection electrode 230_N1 may be inclined, corresponding to a profile of the side surface of the one cell plug CP1.

Referring again to FIG. 5, the plurality of dummy plugs DP may be located in the connection region CON. Each of the plurality of dummy plugs DP may penetrate the gate electrodes 230 and the mold insulating layers 232. The dummy plug DP may extend in the vertical direction Z. The dummy plug DP may extend in the vertical direction Z from the stack cover insulating layer 234 to an upper insulating layer 272 and may penetrate the gate electrodes 230 and the mold insulating layers 232.

In some example embodiments, the length of the dummy plug DP in the vertical direction Z may be greater than the length of the cell plug CP1 in the vertical direction Z. For example, the number of gate electrodes 230 through which the dummy plug DP penetrates may be greater than the number of gate electrodes 230 through which the cell plug CP1 penetrates.

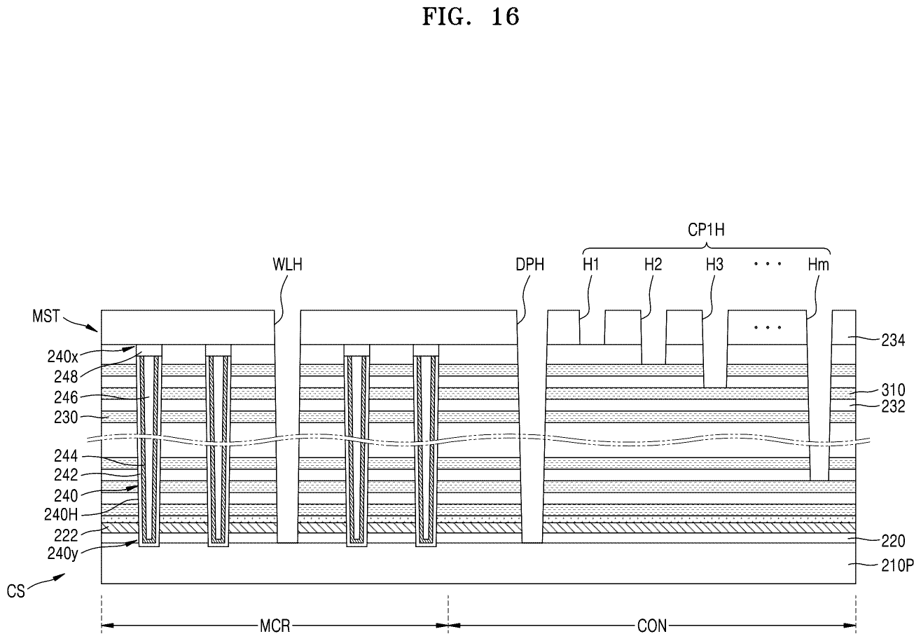

The plurality of dummy plugs DP may surround the plurality of cell plugs CP1, respectively. In the process of forming the plurality of cell plugs CP1, the plurality of dummy plugs DP may suppress leaning or bending of sacrificial layers 310 (see FIG. 16), the gate electrodes 230, and the mold insulating layers 232, thereby ensuring the structural stability.

Referring to FIG. 6, the dummy plug DP may further include protrusions DP_E spaced apart from each other in the vertical direction Z. Each of the protrusions DP_E may protrude in the horizontal direction toward the gate electrode 230 on a side surface DP_S of one dummy plug DP.

The protrusions DP_E may be spaced apart from each other in the vertical direction Z. For example, one mold insulating layer 232 may be located between the protrusions DP_E. For example, a top surface of the one protrusion DP_E may have the same vertical level as a top surface of the gate electrode 230, and a bottom surface of the one protrusion DP_E may have the same vertical level as a bottom surface of the gate electrode 230. For example, the thickness of the protrusion DP_E in the vertical direction Z may be the same as the thickness of the gate electrode 230 in the vertical direction Z.

The gate electrode 230 may include a second side surface 230_S2 facing the one dummy plug DP. For example, while the one dummy plug DP penetrates the gate electrode 230, a side surface defining a hole formed in the gate electrode 230 may include the second side surface 230_S2 of the gate electrode 230.

A second side surface 2301_S2 of the conductive layer 2301 of the gate electrode 230 may face the protrusion DP_E of the one dummy plug DP, and the sidewall 2302_SW of the coating layer 2302 of the gate electrode 230 may cover the second side surface 2301_S2 of the conductive layer 2301.

For example, the second side surface 2301_S2 of the conductive layer 2301 of the gate electrode 230 may be completely covered by the sidewall 2302_SW of the coating layer 2302 of the gate electrode 230. For example, the second side surface 2301_S2 of the conductive layer 2301 of the gate electrode 230 may be spaced apart from the protrusion DP_E of the one dummy plug DP in the horizontal direction with the sidewall 2302_SW of the coating layer 2302 therebetween.

The second side surface of the gate electrode 230 may include an outer surface 2302_SWO of the sidewall 2302_SW of the coating layer 2302 of the gate electrode 230. The protrusion DP_E of the one dummy plug DP may be in contact with the outer surface 2302_SWO of the sidewall 2302_SW of the coating layer 2302 of the gate electrode 230. For example, an inner surface of the sidewall 2302_SW of the coating layer 2302 of the gate electrode 230 may be in contact with the second side surface 2301_S2 of the conductive layer 2301 of the gate electrode 230.

The second side surface 2301_S2 of the conductive layer 2301 of the gate electrode 230 may be covered by the sidewall 2302_SW of the coating layer 2302. For example, the second side surface 2301_S2 of the conductive layer 2301 of the gate electrode 230 may be completely covered by the coating layer 2302, so as to be spaced apart from the protrusion DP_E of the dummy plug DP in the horizontal direction.

For example, a side surface DP_E_S1 of the protrusion DP_E of the dummy plug DP may be in contact with the outer surface 2302_SWO of the sidewall 2302_SW of the coating layer 2302 of the gate electrode 230. The side surface DP_E_S1 of the protrusion DP_E of the dummy plug DP may be coplanar with the outer surface 2302_SWO of the sidewall 2302_SW of the coating layer 2302 of the gate electrode 230.

For example, after the plurality of dummy plugs DP are formed, the gate electrodes 230 may be formed, so that the coating layers 2302 of the gate electrodes 230 are located on the side surfaces DP_E_S1 of the protrusions DP_E of the plurality of dummy plugs DP.

For example, the plurality of dummy plugs DP may be formed of silicon oxide, silicon nitride, silicon oxynitride, an insulating material having a lower permittivity than silicon oxide, or a combination thereof.

For example, after the plurality of dummy plugs DP are formed, the gate electrodes 230 may be formed, and after the gate electrodes 230 are formed, the plurality of cell plugs CP1 may be formed. Accordingly, in the process of forming the recesses in which the protrusions DP_E of the plurality of dummy plugs DP are to be arranged, it is possible to suppress the damage to the insulating spacers 236 surrounding the side surfaces of the plurality of cell plugs CP.

Referring again to FIG. 5, the upper insulating layer 272 may be disposed on the common source layer 210. The upper insulating layer 272 may have a flat top surface throughout the cell region MCR and the connection region CON. A common source contact 274 connected to the common source layer 210 may be arranged through the upper insulating layer 272, and a back wiring layer 276 electrically connected to the common source contact 274 may be disposed on the upper insulating layer 272.

A passivation layer 278 covering the back wiring layer 276 may be disposed on the upper insulating layer 272. The passivation layer 278 may include an opening OP exposing a top surface of the back wiring layer 276.

According to the above-described embodiments, the cell plug CP1 may be formed to penetrate the gate extension 230E, and the insulating spacer 236 may be positioned between each of the gate extensions 230E and the side surface of the cell plug CP1. Therefore, the semiconductor device 100 has a contact structure without steps, so that the area occupied by the connection region CON may be reduced (and/or minimized).

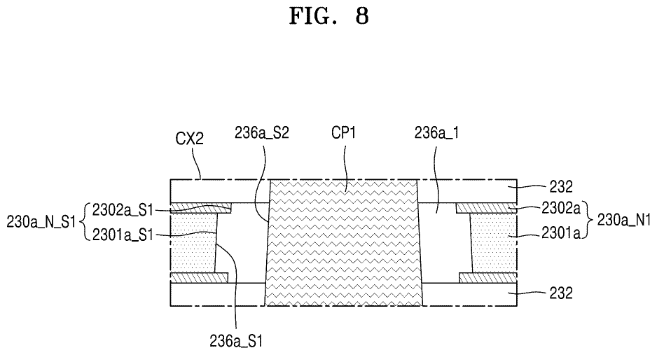

FIGS. 8 to 11 are schematic enlarged views of a portion of the semiconductor device 100, according to some example embodiments. For example, FIGS. 8 to 11 are enlarged views corresponding to portion CX2 in FIG. 6.

In FIGS. 8 to 11, the same reference numerals as in FIGS. 1 to 7 denote the same components. FIGS. 8 to 11 are enlarged views representing a portion corresponding to FIG. 7. Hereinafter, for the convenience of description, differences between FIG. 8 to FIG. 11 and FIG. 7 will be mainly described.

Referring to FIG. 8, a first non-selection electrode 230a_N1 may include a conductive layer 2301a and a coating layer 2302a. A first insulating spacer 236a_1 may include a first side surface 236a_S1 in contact with the first non-selection electrode 230a_N1 and a second side surface 236a_S2 opposite to the first side surface 236a_S1 and in contact with the side surface of the one cell plug CP1.

A first side surface 230a_S1 of the conductive layer 2301a of the first non-selection electrode 230a_N1 may be in contact with the first side surface 236a_S1 of the first insulating spacer 236a_1, and a first side surface 2302a_S1 of the coating layer 2302a of the first non-selection electrode 230a_N1 may be in contact with the first side surface 236_S1 of the first insulating spacer 236a_1. For example, the shape of the first side surface 236a_S1 of the first insulating spacer 236a_1 may correspond to the shape of a first side surface 230a_N_S1 of the first non-selection electrode 230a_N1.

The separation distance between the second side surface 236a_S2 of the first insulating spacer 236a_1 and the first side surface 2301a_S1 of the conductive layer 2301a of the first non-selection electrode 230a_N1 may be greater than the separation distance between the second side surface 236a_S2 of the first insulating spacer 236a_1 and the first side surface 2302a_S1 of the coating layer 2302a of the first non-selection electrode 230a_N1.

For example, the separation distance between the first side surface 2301a_S1 of the conductive layer 2301a of the first non-selection electrode 230a_N1 and the side surface of the one cell plug CP1 may be greater than the separation distance between the first side surface 2302a_S1 of the coating layer 2302a of the first non-selection electrode 230a_N1 and the side surface of the one cell plug CP1.

The width of the first insulating spacer 236a_1 at a part in contact with the conductive layer 2301a of the first non-selection electrode 230a_N1 may be greater than the width of the first insulating spacer 236a_1 at a part in contact with the coating layer 2302a of the first non-selection electrode 230a_N1.

For example, the first side surface 2301a_S1 of the conductive layer 2301a of the first non-selection electrode 230a_N1 may be located between the upper wall and the lower wall of the coating layer 2302a of the first non-selection electrode 230a_N1. For example, the first side surface 2302a_S1 of the coating layer 2302a of the first non-selection electrode 230a_N1 may protrude outside the first side surface 2301a_S1 of the conductive layer 2301a of the first non-selection electrode 230a_N1.

For example, in the process of fabricating a recess for forming the first insulating spacer 236a_1, the first side surface 2301a_S1 of the conductive layer 2301a of the first non-selection electrode 230a_N1 may be located between the upper wall and the lower wall of the coating layer 2302a, depending on the degree to which each of the coating layer 2302a and the conductive layer 2301a of the first non-selection electrode 230a_N1 is etched. Accordingly, the first insulating spacer 236a_1 may include regions having different widths.

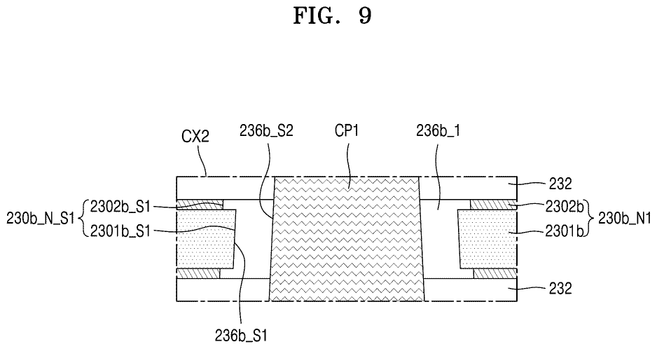

Referring to FIG. 9, a first non-selection electrode 230b_N1 may include a conductive layer 2301b and a coating layer 2302b. A first insulating spacer 236b_1 may include a first side surface 236b_S1 in contact with the first non-selection electrode 230b_N1 and a second side surface 236b_S2 opposite to the first side surface 236a_S1 and in contact with a side surface of the one cell plug CP1.

The separation distance between the second side surface 236b_S2 of the first insulating spacer 236b_1 and a first side surface 2301b_S1 of the conductive layer 2301b of the first non-selection electrode 230b_N1 may be less than the separation distance between the second side surface 236b_S2 of the first insulating spacer 236b_1 and a first side surface 2302b_S1 of the coating layer 2302b of the first non-selection electrode 230b_N1.

For example, the separation distance between the first side surface 2302b_S1 of the coating layer 2302b and the side surface of the one cell plug CP1 may be greater than the separation distance between the first side surface 2301b_S1 of the conductive layer 2301b and the side surface of the one cell plug CP1.

The width of the first insulating spacer 236b_1 at a part of the first non-selection electrode 230b_N1 in contact with the conductive layer 2301b may be less than the width of the first insulating spacer 236b_1 at a part in contact with the coating layer 2302b of the first non-selection electrode 230b_N1.

For example, the first side surface 2302b_S1 of the coating layer 2302b of the first non-selection electrode 230b_N1 may be located on the top surface or the bottom surface of the conductive layer 2301b of the first non-selection electrode 230b_N1. For example, the first side surface 2301b_S1 of the conductive layer 2301b of the first non-selection electrode 230b_N1 may protrude outside the first side surface 2302b_S1 of the coating layer 2302b of the first non-selection electrode 230b_N1.

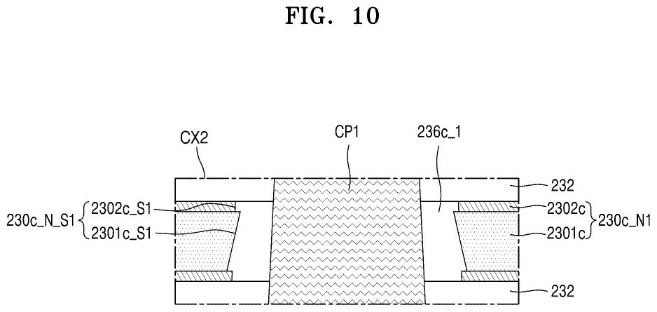

Referring to FIG. 10, a first non-selection electrode 230c_N1 may include a conductive layer 2301c and a coating layer 2302c. A first side surface 2301c_S1 of the conductive layer 2301c of the first non-selection electrode 230c_N1 may face the cell plug CP1 and may be in contact with a first insulating spacer 236c_1, and a first side surface 2302c_S1 of the coating layer 2302c of the first non-selection electrode 230c_N1 may face the cell plug CP1 and may be in contact with the first insulating spacer 236c_1.

The first side surface 2301c_S1 of the conductive layer 2301c of the first non-selection electrode 230c_N1 and the first side surface 2302c_S1 the coating layer 2302c of the first non-selection electrode 230c_N1 may be inclined. For example, the inclination of the first side surface 2301c_S1 of the conductive layer 2301c of the first non-selection electrode 230c_N1 may be different from the inclination of the first side surface 2302c_S1 of the coating layer 2302c of the first non-selection electrode 230c_N1.

For example, etching of the conductive layer 2301c of the first non-selection electrode 230c_N1 may be performed separately from etching of the coating layer 2302c of the first non-selection electrode 230c_N1. Accordingly, the etching environment of the conductive layer 2301c of the first non-selection electrode 230c_N1 may be different from the etching environment of the coating layer 2302c of the first non-selection electrode 230c_N1, and thus the inclination of the first side surface 2301c_S1 of the conductive layer 2301c of the first non-selection electrode 230c_N1 may be different from the inclination of the first side surface 2302c_S1 of the non-selection electrode 230c_N1.

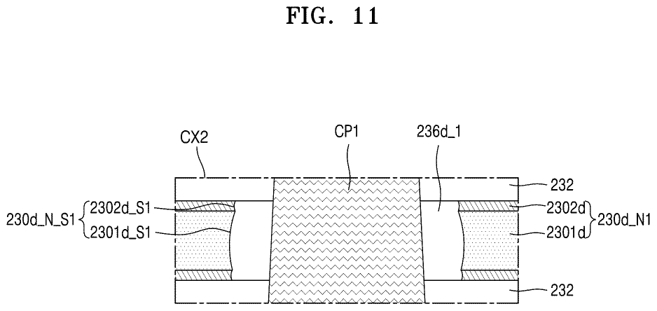

Referring to FIG. 11, a first non-selection electrode 230d_N1 may include a conductive layer 2301d and a coating layer 2302d. A first side surface 2301d_S1 of the conductive layer 2301d of the first non-selection electrode 230d_N1 may face the cell plug CP1 and may be in contact with a first insulating spacer 236d_1, and a first side surface 2302d_S1 of the coating layer 2302d of the first non-selection electrode 230d_N1 may face the cell plug CP1 and may be in contact with the first insulating spacer 236d_1.

The first side surface 2301d_S1 of the conductive layer 2301d of the first non-selection electrode 230d_N1 may include an inwardly concave curved surface. The first side surface 2302d_S1 of the coating layer 2302d of the first non-selection electrode 230d_N1 may include an inwardly concave curved surface. For example, in the process of forming a recess in which the first insulating spacer 236d_1 is to be located, the first side surface 2301d_S1 of the conductive layer 2301d of the first non-selection electrode 230d_N1 and the first side surface 2302d_S1 of the coating layer 2302d of the first non-selection electrode 230d_N1 may include a concave curved surface.

In some example embodiments, for example, the process of etching the conductive layer 2301d of the first non-selection electrode 230d_N1 and the process of etching the coating layer 2302d of the first non-selection electrode 230d_N1 may be performed separately, so that only one side surface of the first side surface 2301d_S1 of the conductive layer 2301d of the first non-selection electrode 230d_N1 and the first side surface 2302d_S1 of the coating layer 2302d of the first non-selection electrode 230d_N1 includes a curved surface.

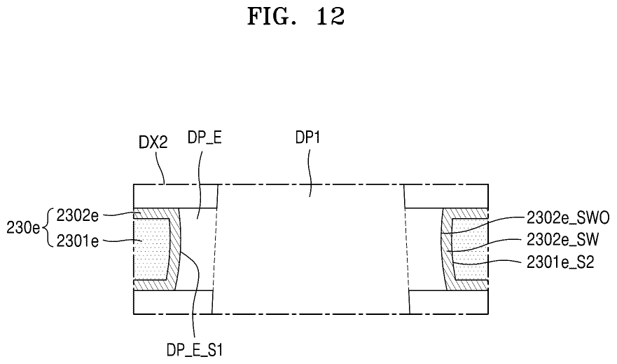

FIG. 12 is a schematic enlarged view of a portion of the semiconductor device 100 according to some example embodiments. For example, FIG. 12 is an enlarged view corresponding to portion DX2 in FIG. 6. For the convenience of description, differences between FIG. 12 and portion DX2 in FIG. 6 are mainly described below.

Referring to FIG. 12, each of gate electrodes 230e may include a conductive layer 2301e and a coating layer 2302e surrounding the conductive layer 2301e. The conductive layer 2301e of the gate electrode 230e may include a second side surface 2301e_S2 facing the one dummy plug DP. The coating layer 2302e of the gate electrode 230e may include a sidewall 2302e_SW located on the second side surface 2301e_S2 of the conductive layer 2301e.

The sidewall 2302e_SW of the coating layer 2302e of the gate electrode 230e may be positioned between the conductive layer 2301e of the gate electrode 230e and the protrusion DP_E of the dummy plug DP. An outer surface 2302e_SWO of the sidewall 2302e_SW of the coating layer 2302e of the gate electrode 230e may be in contact with the side surface DP_E_S1 of the protrusion DP_E of the dummy plug DP.

In some example embodiments, the second side surface 2301e_S2 of the conductive layer 2301e of the gate electrode 230e may include an outwardly convex curved surface. For example, the sidewall 2302e_SW of the coating layer 2302e of the gate electrode 230 e may be conformally formed on the second side surface 2301e_S2 of the conductive layer 2301e of the gate electrode 230e. For example, the outer surface 2302e_SWO of the sidewall 2302e_SW of the coating layer 2302e of the gate electrode 230e may include an outwardly convex curved surface.

In some example embodiments, the side surface DP_E_S1 of the protrusion DP_E of the dummy plug DP may include an inwardly concave curved surface. For example, the side surface DP_E_S1 of the protrusion DP_E of the dummy plug DP may be coplanar with the outer surface 2302e_SWO of the sidewall 2302e_SW of the coating layer 2302e of the gate electrode 230e.

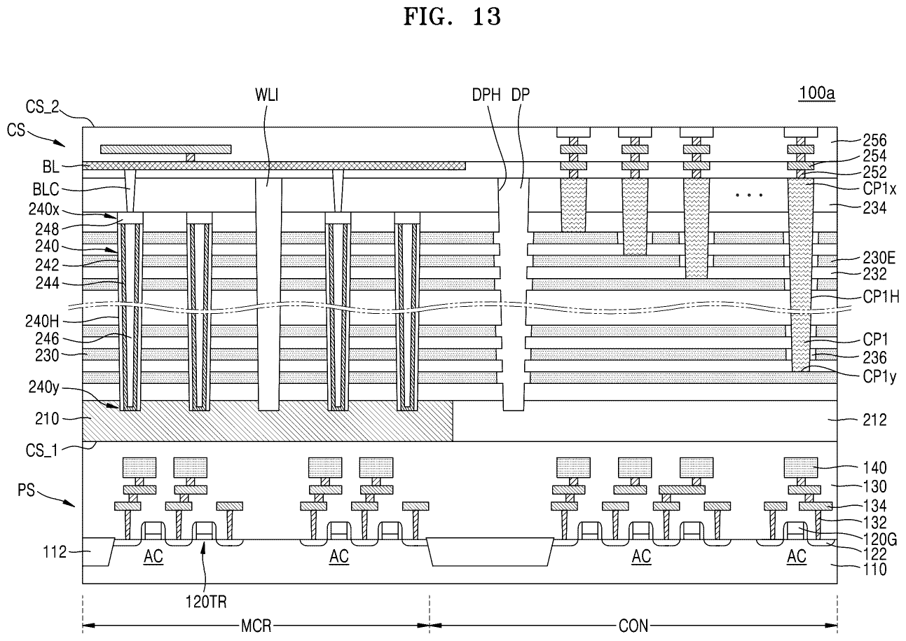

FIG. 13 is a schematic cross-sectional view of a portion of a semiconductor device 100a according to some example embodiments. For example, FIG. 13 shows the semiconductor device 100a in which the cell structure CS is disposed on the peripheral circuit structure PS so that the bit line BL of the cell structure CS extends upward in the vertical direction Z. For example, the bit line BL shown in FIG. 13 extends on an upper surface of the cell structure CS with respect to the vertical direction Z. For the convenience of description, differences between the semiconductor device 100a of FIG. 13 and the semiconductor device 100 of FIG. 5 are mainly described below.

Referring to FIG. 13, the common source layer 210 is disposed on the peripheral circuit structure PS in the cell region MCR, and a buried insulating layer 212 may be disposed on the peripheral signal structure PS in the connection region CON. The gate electrodes 230 and the mold insulating layers 232 may be disposed on the common source layer 210 and the buried insulating layer 212.

The channel structure 240 may have an inclined sidewall such that the width of the first end 240x is greater than the width of the second end 240y. The second end 240y of the channel structure 240 may be arranged close to the peripheral circuit structure PS, and the first end 240x of the channel structure 240 may be arranged away from the peripheral circuit structure PS.

In some example embodiments, the cell plug CP1 has the first end CP1x and the second end CP1y, wherein the first ends CP1x of the plurality of cell plugs CP1 are all arranged at the same vertical level and may also be arranged at the same vertical level as the top surface of the stack cover insulating layer 234. The second ends CP1y of the plurality of cell plugs CP1 may be arranged at different vertical levels.

The second ends CP1y of the plurality of cell plugs CP1 may be arranged close to the peripheral circuit structure PS and the first ends CP1x of the plurality of cell plugs CP1 may be arranged away from the peripheral circuit structure PS.

For example, referring to FIG. 6 together, among the gate electrodes 230, the gate electrode 230 in contact with the second end CP1y of the one cell plug CP1 may be referred to as the selection electrode 230_S corresponding to the one cell plug CP1. The one cell plug CP1 may be electrically connected to the selection electrode 230_S. The selection electrodes 230_S corresponding to the plurality of cell plugs CP1 may be different from each other.

The gate electrode 230 in contact with the one cell plug CP1 may be referred to as the selection electrode 230_S corresponding to the one cell plug CP1, and the gate electrode 230 through which the one cell plug CP1 passes may be referred to as the non-selection electrode 230_N corresponding to the one cell plug CP1. For example, the non-selection electrodes 230_N may be gate electrodes 230 located at a higher vertical level than the selection electrode 230_S.

The second side surface 2301_S2 of the conductive layer 2301 of the gate electrode 230 may be completely covered by the sidewall 2302_SW of the coating layer 2302 of the gate electrode 230, and the first side surface 2301_S1 of the conductive layer 2301 of the non-selection electrode 230_N of the gate electrodes 230 may be completely covered by the insulating spacer 236. For example, the second side surface 2301_S2 of the conductive layer 2301 of the gate electrode 230 may be spaced apart from the dummy plug DP, and the first side surface 2301_S1 of the conductive layer 2301 of the non-selection electrode 230_N may be in contact with the insulating spacer 236.

The peripheral circuit structure PS may include a landing pad 140, and the peripheral plug CP2 extending in the vertical direction Z may be electrically connected to the landing pad 140.

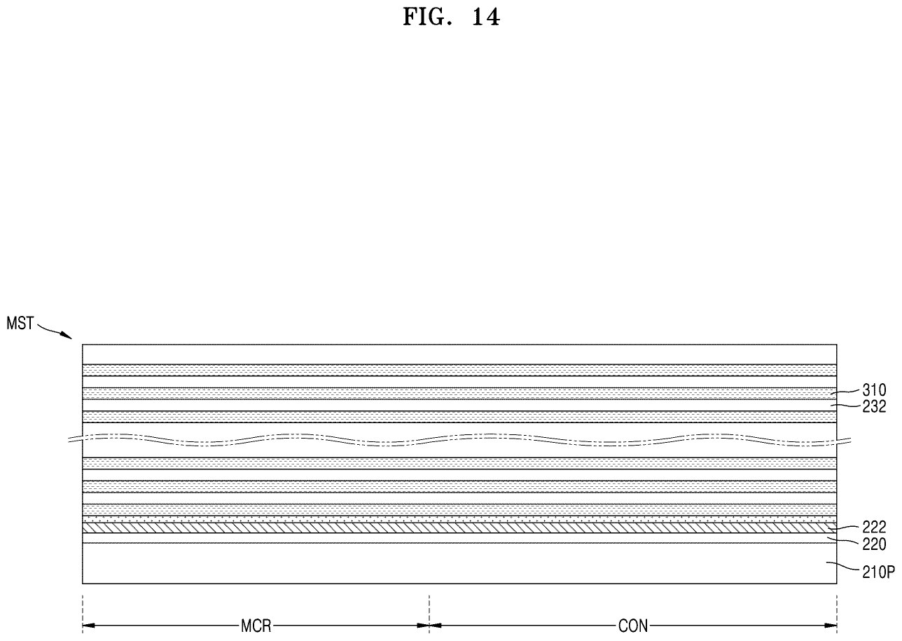

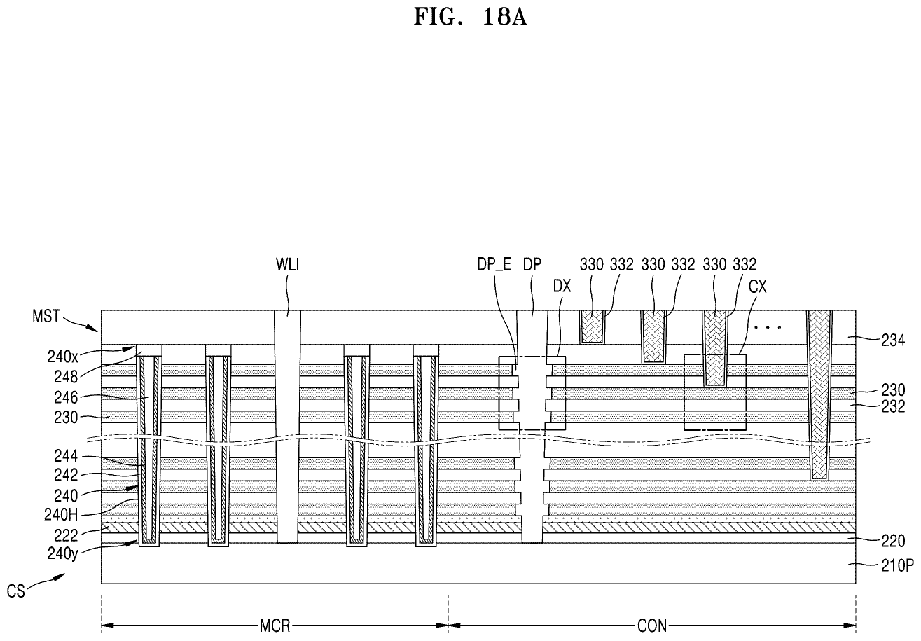

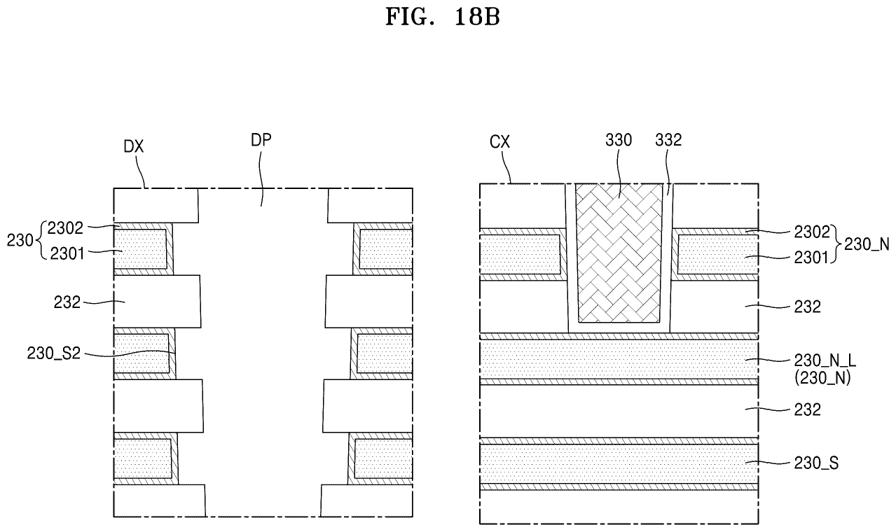

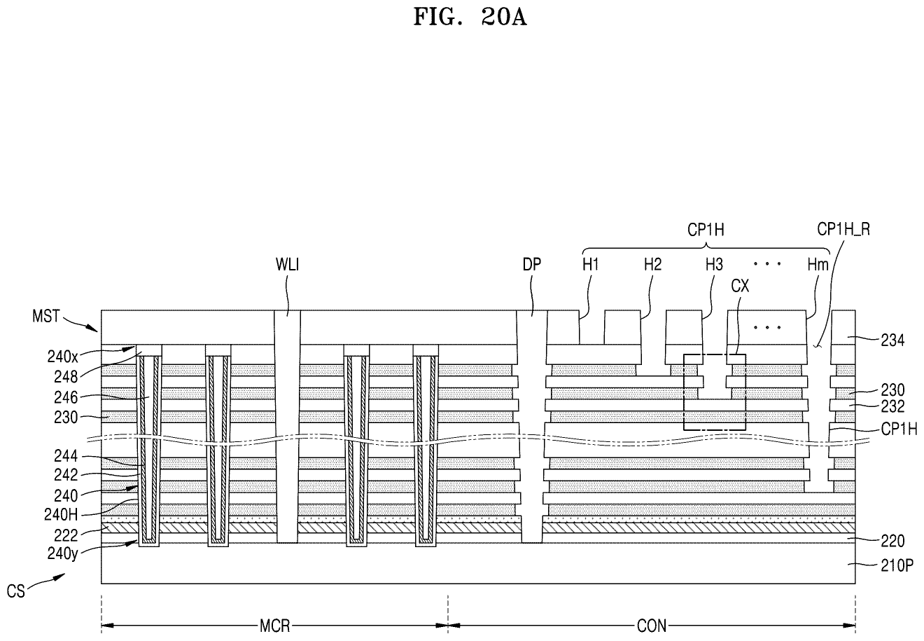

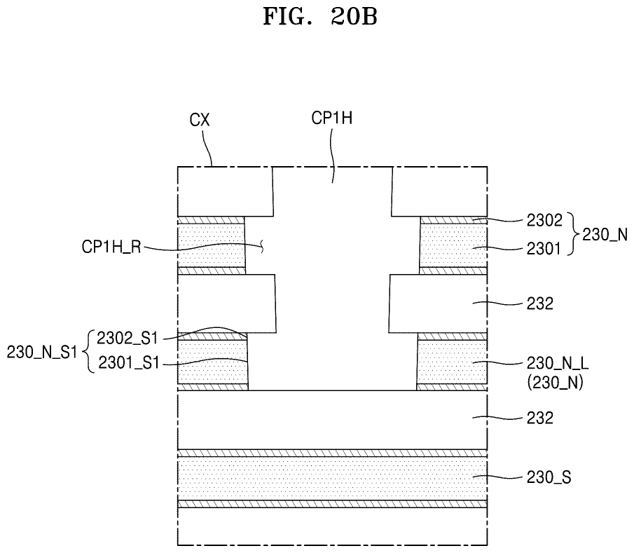

FIGS. 14 to 29 are cross-sectional views illustrating a method of manufacturing the semiconductor device according to some example embodiments, wherein for example, FIGS. 14 to 17, 18A, 19, 20A, 21A, 22A, 23A, and 24 to 29 are cross-sectional views corresponding to a cross-section taken along line A-A′ in FIG. 4, FIG. 18B is an enlarged view of portion DX and portion CX in FIG. 18A, and FIGS. 20B, 21B, 22B, and 23B are enlarged views of portion CX in FIGS. 20A, 21A, 22A, and 23A.

Referring to FIG. 14, a buffer insulating layer 220 may be formed on a cell substrate 210P, and the etch stop layer 222 may be formed on the buffer insulating layer 220.

In some example embodiments, the cell substrate 210P may include at least one of Si, Ge, SiGe, GaAs, InGaAs, AlGaAs, or a mixture thereof. The buffer insulating layer 220 may be formed using silicon oxide. In some example embodiments, the etch stop layer 222 may be formed using polysilicon.

Thereafter, the sacrificial layers 310 and the mold insulating layers 232 may be alternately formed on the etch stop layer 222 in the cell region MCR and the connection region CON to form a mold stack MST.

In some example embodiments, the sacrificial layers 310 and the mold insulating layers 232 may be formed using a material having an etch selectivity with respect to each other. For example, the sacrificial layers 310 may include silicon nitride, and the mold insulating layers 232 may include silicon oxide.

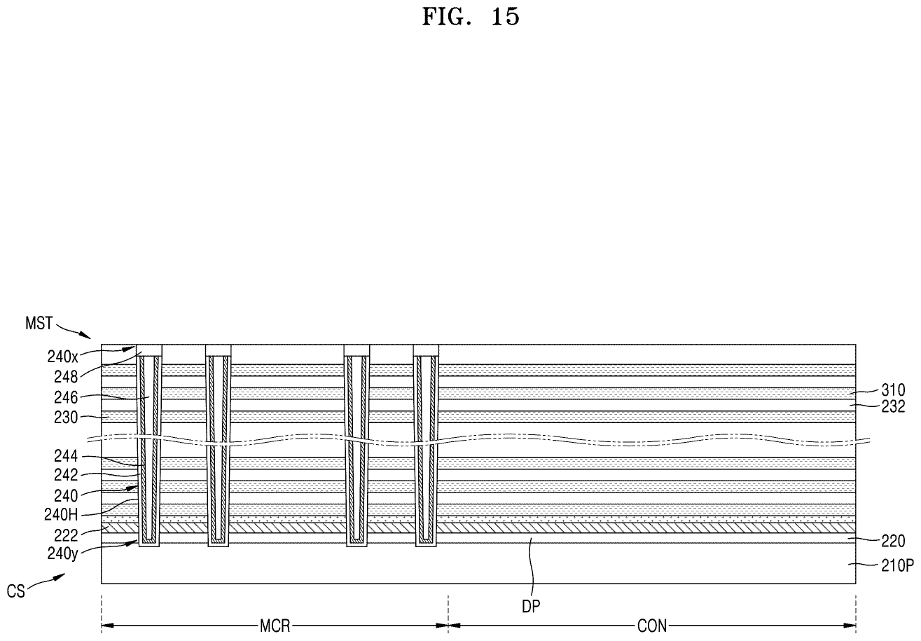

Referring to FIG. 15, the channel structure 240 extending in the vertical direction Z through the mold stack MST in the cell region MCR may be formed.

In some example embodiments, in the process for forming the channel structure 240, the channel hole 240H passing through the mold stack MST may be formed in the cell region MCR, the gate insulating layer 242, the channel layer 244, and the buried insulating layer 246 may be sequentially formed on an inner wall of the channel hole 240H, and the drain region 248 may be formed at an inlet of the channel hole 240H.

In some example embodiments, the channel hole 240H may extend in the vertical direction Z through the mold stack MST, the etch stop layer 222, and the buffer insulating layer 220, and the top surface of the cell substrate 210P may be exposed to the bottom of the channel hole 240H.

The channel structure 240 may have the first end 240x and the second end 240y that is opposite thereto. The first end 240x may be adjacent to the top surface of the mold stack MST or may be arranged at the same vertical level as the top surface of the mold stack MST. The second end 240y of the channel structure 240 may be in contact with the top surface of the cell substrate 210P and may be arranged at a lower vertical level than the top surface of the cell substrate 210P. In some example embodiments, the horizontal width of the first end 240x of the channel structure 240 may be greater than the horizontal width of the second end 240y of the channel structure 240.

Referring to FIG. 16, the stack cover insulating layer 234 may be formed on the top surface of the mold stack MST. The stack cover insulating layer 234 may cover the entire top surface of the mold stack MST in the cell region MCR and the connection region CON. The stack cover insulating layer 234 may have flat top surface and bottom surface levels over the entire area of the cell region MCR and the connection region CON and may have a constant thickness over the entire area of the cell region MRC and the connection region CON.

Thereafter, the stack isolation opening WLH extending in the vertical direction Z through the mold stack MST and the stack cover insulating layer 234 in the cell region MCR and the connection region CON is formed. The stack isolation opening WLH may extend in the first horizontal direction X (see FIG. 4) in the cell region MCR and the connection region CON.

A plurality of dummy plug holes DPH extending in the vertical direction Z through the mold stack MST may be formed in the connection region CON. In some example embodiments, the process for forming the plurality of dummy plug holes DPH may be performed simultaneously with the etching process for forming the stack isolation opening WLH. In some other example embodiments, the process for forming the plurality of dummy plug holes DPH may be performed simultaneously with the etching process for forming the channel structure 240.

The stack cover insulating layer 234 and the mold stack MST in the connection region CON may be partially removed to form a plurality of cell plug holes CP1H extending in the vertical direction Z. The plurality of cell plug holes CP1H may have heights that vary along the vertical direction Z. The plurality of cell plug holes CP1H may have different heights so as to expose a top surface of a sacrificial layer 310 among the plurality of sacrificial layers 310.

For example, each of the plurality of cell plug holes CP1H may include a first hole H1 exposing the top surface of the uppermost mold insulating layer 232, a second hole H2 exposing the top surface of the uppermost sacrificial layer 310, a third hole H3 exposing the top surface of the sacrificial layer 310 immediately below the uppermost sacrificial layer 310, and an m^{th} hole Hm exposing the top surface of the m^{th} sacrificial layer 310 from the top surface of the mold stack MST.

For example, the cell plug hole CP1H may expose the top surface of the sacrificial layer 310 located one layer higher than the sacrificial layer 310 on which the selection electrode 230_S corresponding to the cell plug CP1 to be formed in the cell plug hole CP1H is to be formed. For example, the cell plug hole CP1H may expose the top surface of the sacrificial layer 310 on which the lowermost non-selection electrode 230_N_L among the non-selection electrodes 230_N corresponding to the cell plug CP1 to be formed inside the cell plug hole CP1H is to be formed.

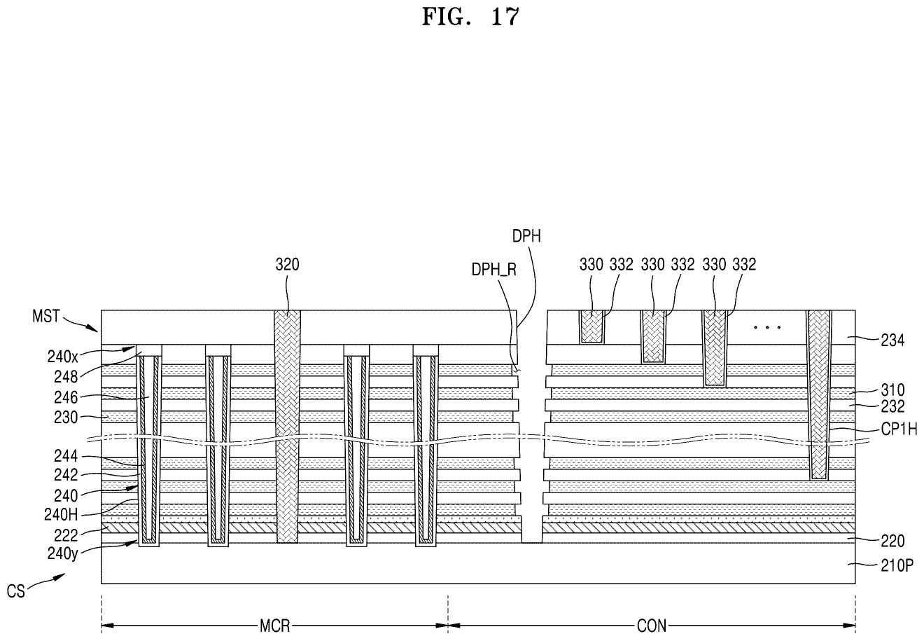

Referring to FIG. 17, a first protective layer 320 may be formed in the stack isolation opening WLH, and a second protective layer 330 may be formed in the cell plug hole CP1H. Thereafter, a dummy recess process may be performed to remove a part of the sacrificial layers 310 exposed to the inner wall of each of the plurality of dummy plug holes DPH. In some example embodiments, after the insulating layer 332 is formed on the inner wall of the cell plug hole CP1H, the second protective layer 330 may be formed.

In some example embodiments, the dummy recess process may include a process for removing a side surface of the sacrificial layer 310 exposed to the inner wall of the dummy plug hole DPH by a certain thickness. In some example embodiments, the dummy recess process may include a wet etching process using an etchant including phosphoric acid or a dry etching process.

As the side portion of the sacrificial layer 310 exposed to the inner wall of the dummy plug hole DPH is removed by the dummy recess process, the side surface of the sacrificial layer 310 may be retracted, dented, or recessed inward from the side surface of the mold insulating layer 232.

Accordingly, a dummy recess region DPH_R may be defined in the space between the two mold insulating layers 232 adjacent to each other in the vertical direction Z and between the sidewalls of the sacrificial layer 310. The horizontal distance between the side surface of the sacrificial layer 310 and the side surface of the mold insulating layer 232 may be defined as the width of the dummy recess region DPH_R in the horizontal direction.

Referring to FIGS. 18A and 18B, the dummy plug DP may be formed by filling the inside of each of the plurality of dummy plug holes DPH with an insulating material. For example, the dummy recess region DPH_R may also be filled with an insulating material to form the protrusion DP_E of the dummy plug DP.

Thereafter, the first protective layer 320 arranged within the stack isolation opening WLH may be removed, and the sacrificial layer 310 exposed to the inner wall of the stack isolation opening WLH may be removed. Thereafter, the gate electrode 230 may be formed using a metal material in the space from which the sacrificial layer 310 is removed. Thereafter, the stack isolation insulating layer WLI may be formed in the stack isolation opening WLH.

For example, in the process of forming the gate electrode 230, the coating layer 2302 may be first formed, and then the conductive layer 2301 may be formed inside the coating layer 2302. For example, the conductive layer 2301 may be surrounded by the coating layer 2302.

For example, the conductive layer 2301 of the gate electrode 230 may be spaced apart from the protrusion DP_E of the dummy plug DP with the coating layer 2302 positioned therebetween. For example, the conductive layer 2301 of the gate electrode 230 penetrated by the cell plug hole CP1H among the gate electrodes 230 may be spaced apart from the second protective layer 330 or the insulating layer 332 with the coating layer 2302 positioned therebetween.

As the plurality of sacrificial layers 310 are replaced with the plurality of gate electrodes 230, the plurality of gate electrode 230 may extend in the horizontal direction in the cell region MCR and the connection region CON. The gate electrodes 230 in the connection region CON are referred to as the gate extensions 230E. The plurality of gate extensions 230E may overlap with each other in the vertical direction Z in the connection region CON. For example, the plurality of gate extensions 230E arranged at different vertical levels in the connection region CON may have the same width in the horizontal direction.

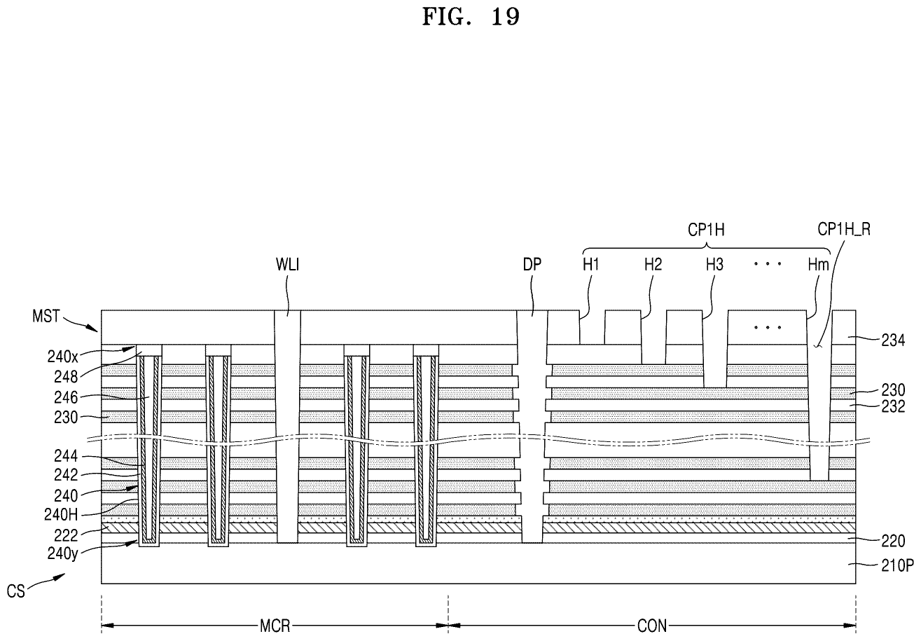

Referring to FIGS. 19, 20A, and 20B, a cell recess process may be performed to remove the second protective layer 330 and the insulating layer 332 arranged inside the cell plug hole CP1H and to remove parts of the gate electrodes 230 exposed to the inner wall of the cell plug hole CP1H.

For example, the gate electrodes 230 exposed by the inner wall and the bottom surface of the cell plug hole CP1H may include the non-selection electrodes 230_N corresponding to the cell plug CP1 to be formed in the cell plug hole CP1H.

For example, the gate electrode 230 exposed by the bottom surface of the cell plug hole CP1H may include the lowermost non-selection electrode 230_N_L corresponding to the cell plug CP1 to be formed in the cell plug hole CP1H.

The cell recess process may include a process for securing a space where the insulating spacers 236 in contact with the non-selection electrodes 230_N are to be formed. In some example embodiments, the cell recess process may include a process for removing the first side surface of the gate electrodes 230 exposed to the inner wall of the plurality of cell plug holes CP1H by a certain thickness and removing the top surface of the gate electrode 230 exposed to the bottom surface of each of the plurality of the cell plug holes CP1H by a certain thickness.

For example, the cell recess process may include a first etching process to remove the coating layer 2302 of the gate electrode 230 and a second etching process to remove a part of the conductive layer 2301 of the gate electrode 230.

The first etching process may be performed to remove the coating layer 2302 of the gate electrode 230 exposed by the inner wall and the bottom surface of the cell plug hole CP1H, so that the conductive layer 2301 of the gate electrode 230 is exposed to the outside.

Thereafter, the second etching process may be performed to remove the first side surface 2301_S1 exposed to the outside of the conductive layer 2301 of the non-selection electrode 230_N by a certain thickness. In addition, the second etching process may be performed to remove the top surface of the lowermost non-selection electrode 230_N_L, among the gate electrodes 230, of which the top surface is exposed by the plurality of cell plug holes CP1H, by a certain thickness.

For example, the second etching process may remove the top surface of the lowermost non-selection electrode 230_N_L until the top surface of the mold insulating layer 232 positioned immediately below the lowermost non-selection electrode 230_N_L is exposed.

As the first side surfaces 230_N_S1 of the non-selection electrodes 230_N exposed to the inner walls of the plurality of cell plug holes CP1H are removed by performing the cell recess process, the first side surfaces 230_N_S1 of the non-selection electrodes 230_N may be retracted, dented, or recessed inward from the side surfaces of the mold insulating layers 232.

Accordingly, a cell recess region CP1H_R may be defined in the space between the two mold insulating layers 232 adjacent to each other in the vertical direction Z and between the first side surfaces 230_N_S1 of the non-selection electrodes 230_N. The horizontal distance by which the first side surface 230_N_S1 of the non-selection electrode 230_N is spaced apart from the side surface of the mold insulating layer 232 may be defined as the width of the cell recess region CP1H_R in the horizontal direction.

For example, after the gate electrodes 230 are formed, the cell recess process may be performed so that the first side surface 2301_S1 of the conductive layer 2301 of the non-selection electrode 230_N is not covered by the coating layer 2302 and is exposed to the outside.

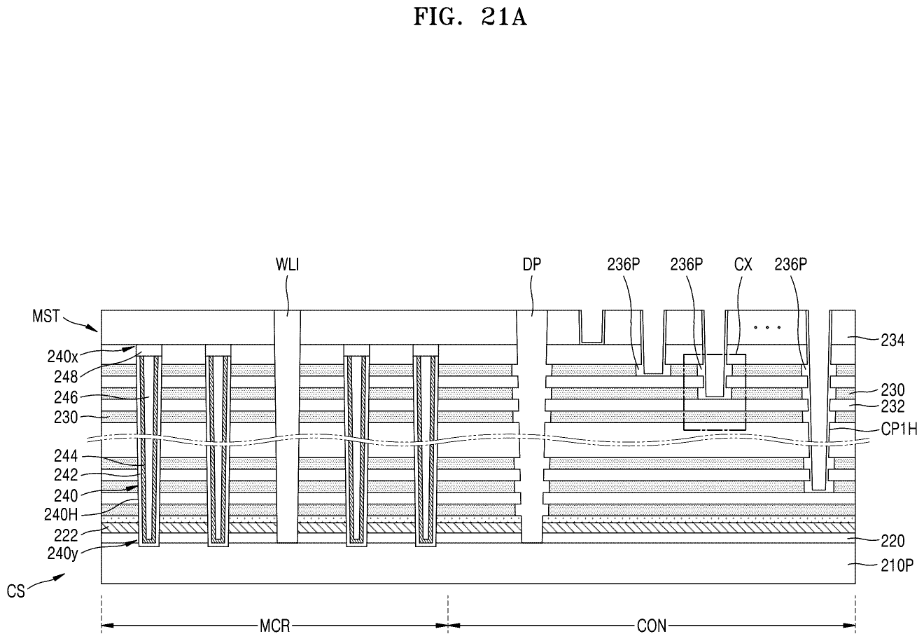

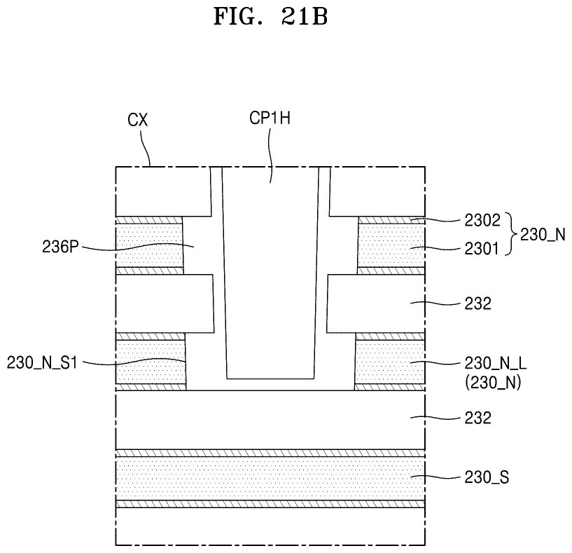

Referring to FIGS. 21A and 21B, spare spacers 236P may be formed on the inner walls and the bottom surfaces of the plurality of cell plug holes CP1H. The spare spacer 236P may fill the interior of the cell recess region CP1H_R. For example, the spare spacers 236P may be located on side surfaces of the mold insulating layers 232 and the first side surfaces 230_N_S1 of the non-selection electrodes 230_N (see FIG. 7).

For example, the width of the parts of the spare spacers 236P located on side surfaces of the mold insulating layers 232 may be narrower than the width of the parts of the spare spacers 236P located on the first side surfaces 230_N_S1 of the non-selection electrodes 230_N.

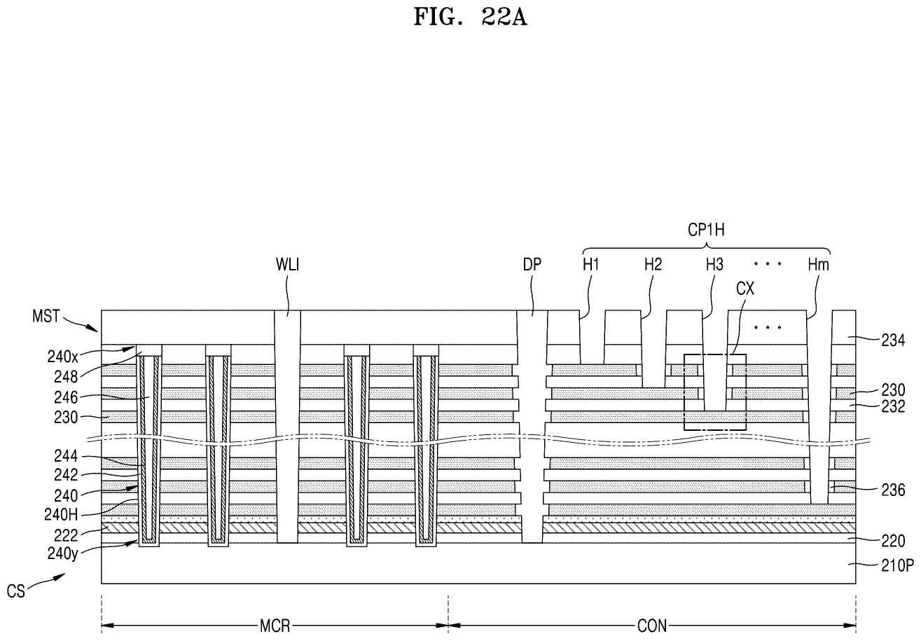

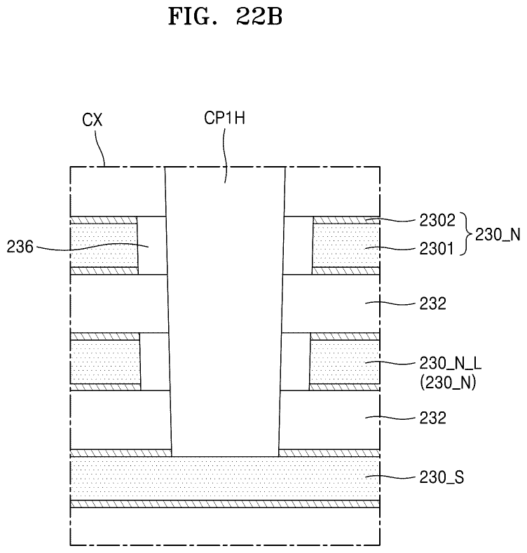

Referring to FIGS. 22A and 22B, the top surface of the mold insulating layer 232 located immediately below the lowermost non-selection electrode 230_N_L may be removed by a certain thickness to expose the top surface of the selection electrode 230_S.

For example, a part of the spare spacer 236P and a part of the mold insulating layer 232 whose top surface is exposed may be removed through the etching process, such as an etch back, to expose the top surface of the selection electrode 230_S.

In some example embodiments, in the etching process, parts of the spare spacers 236P which are relatively narrow and located on side surfaces of the mold insulating layers 232 may be completely removed, and parts of the relative wide spare spacers 236P located on the first side surfaces 230_N_S1 of the non-selection electrodes 230_N may remain.

For example, the insulating spacers 236 may be parts of the spare spacers 236P located inside the cell recess region CP1H_R and may be parts of the spare spacers 236P that have not been removed during the etching process.

The insulating spacer 236 may be in contact with the first side surface 230_N_S1 of the non-selection electrode 230_N. The insulating spacer 236 may be in direct contact with the first side surface 2301_S1 of the conductive layer 2301 of the non-selection electrode 230_N. The thickness of the insulating spacer 236 may be the same as the thickness of the non-selection electrode 230_N.

For example, a part of the mold insulating layer 232 located between the selection electrode 230_S and the lowermost non-selection electrode 230_N_L may be removed. For example, the top surface of the mold insulating layer 232 that is exposed by the cell plug hole CP1H may be removed until the selection electrode 230_S is exposed.

For example, in the process of removing the top surface of the mold insulating layer 232 that is exposed by the cell plug hole CP1H, a part of the upper wall of the coating layer 2302 of the selection electrode 230_S may be removed. Accordingly, the top surface of the conductive layer 2301 of the selection electrode 230_S may be exposed to the outside.

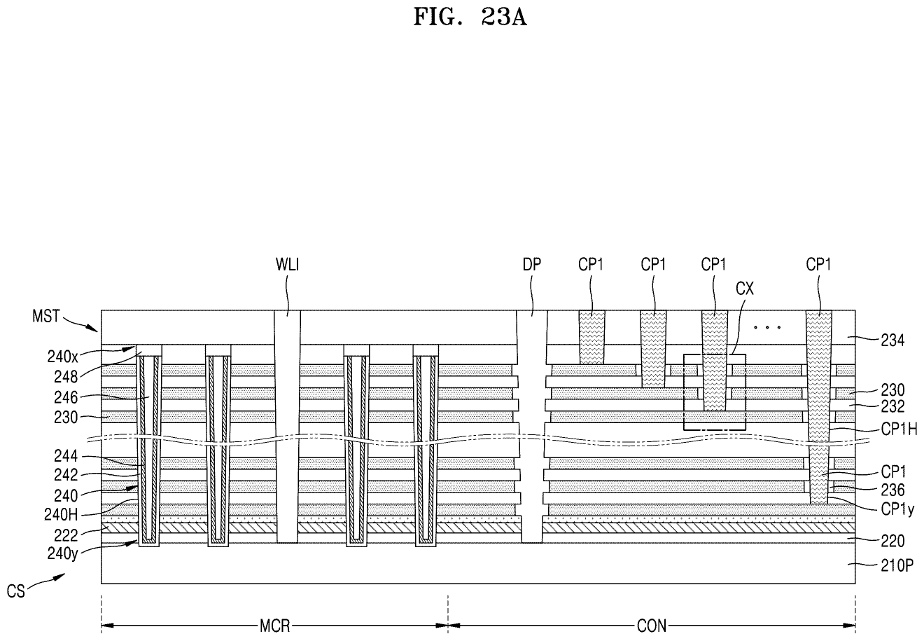

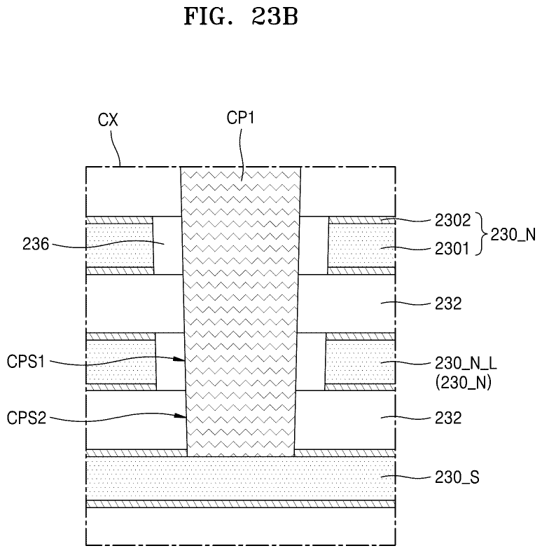

Referring to FIGS. 23A and 23B, the plurality of cell plugs CP1 may be formed inside the plurality of cell plug holes CP1H. The cell plug CP1 may have the plurality of first side portions CPS1 and the plurality of second side portions CPS2 arranged alternately with each other. The plurality of first side portions CPS1 may be in contact with the insulating spacers 236, respectively, and the plurality of second side portions CPS2 may be in contact with the plurality of mold insulating layers 232, respectively.

In some example embodiments, the cell plug CP1 may have the first end CP1x and the second end CP1y, wherein the first end CP1x of the cell plug CP1 may be arranged at the same vertical level as the top surface of the stack cover insulating layer 234 and the second end CP1y thereof may be disposed on the conductive layer 2301 of the selection electrode 230_S. The side surface of the cell plug CP1 may be in contact with the coating layer 2302 of the selection electrode 230_S. Accordingly, the cell plug CP1 may be electrically connected to the selection electrode 230_S.

For example, the bottom surface of the one cell plug CP1 may be electrically connected to the selection electrode 230_S, while the side surface of the one cell plug CP1 may not be electrically connected to the non-selection electrode 230_N arranged at a higher vertical level than the selection electrode 230_S.

The insulating spacer 236 may be positioned between the non-selection electrode 230_N arranged at a higher vertical level than the selection electrode 230_S corresponding to the cell plug CP1 and the side surface of the cell plug CP1, so that the non-selection electrode 230_N and the sidewall of the one cell plug CP1 may be insulated from each other.

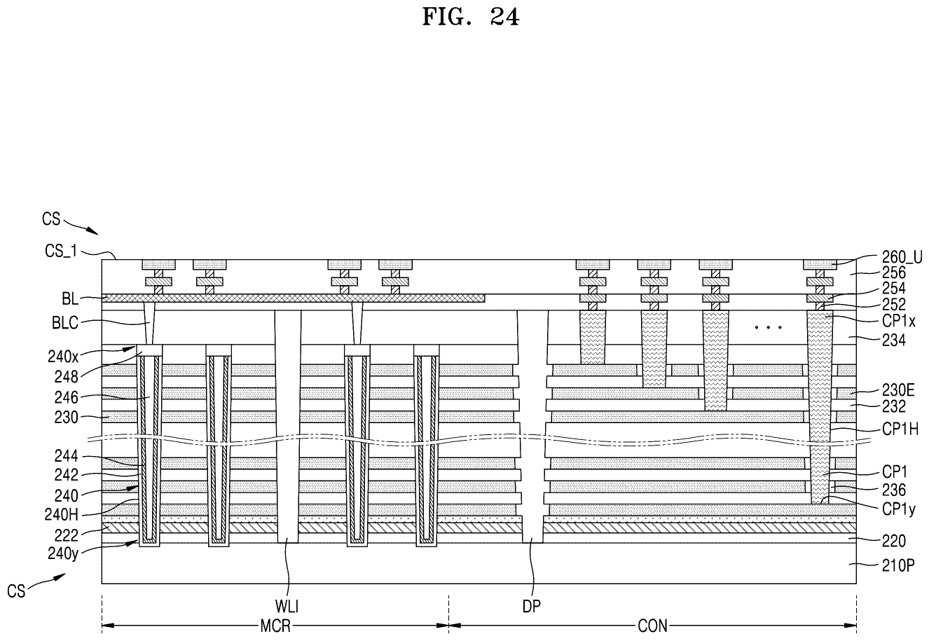

Referring to FIG. 24, the bit line contact BLC and the bit line BL that are electrically connected to the channel structure 240 may be formed.

Thereafter, the connection via 252 and the connection wiring layer 254 which are electrically connected to the bit line BL and the cell plug CP1, and the interlayer insulating film 256 may be formed. A connection pad 260_U may be formed on the top surface of the interlayer insulating film 256.

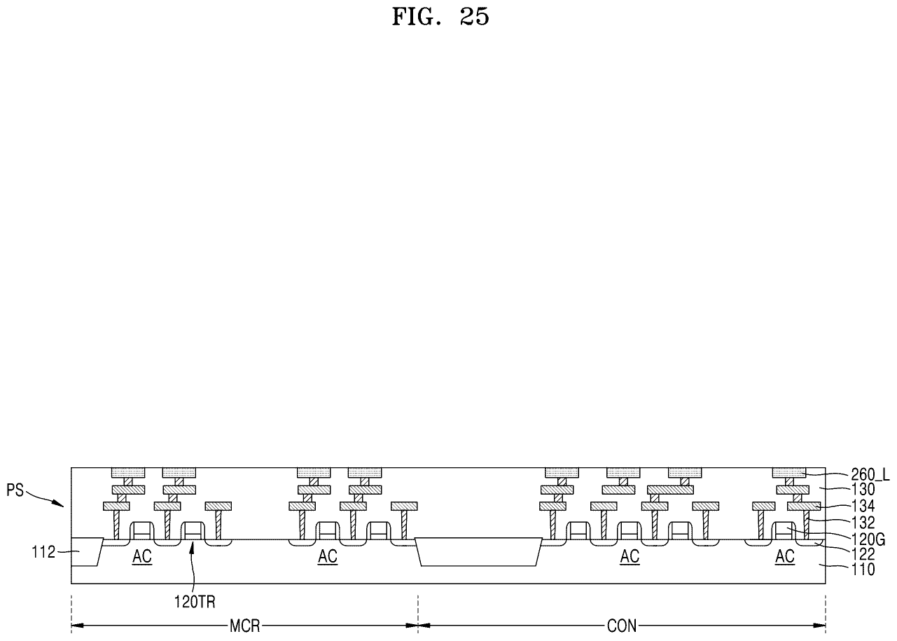

Referring to FIG. 25, the peripheral circuit structure PS may be prepared.

The peripheral circuit transistor 120TR may be formed on the substrate 110 in which the active region AC is defined by the device isolation film 112, a plurality of peripheral circuit transistors 60TR and the plurality of peripheral circuit contacts 132 and the plurality of peripheral circuit wiring layers 134 electrically connected to the substrate 110 may be formed on the substrate 110, and an interlayer insulating film 130 covering the plurality of peripheral circuit transistors 60TR, the plurality of peripheral circuit contacts 132, and the plurality of peripheral circuit wiring layers 134 may be formed on the substrate 110. A connection pad 260_L may be formed on the top surface of the interlayer insulating film 130.

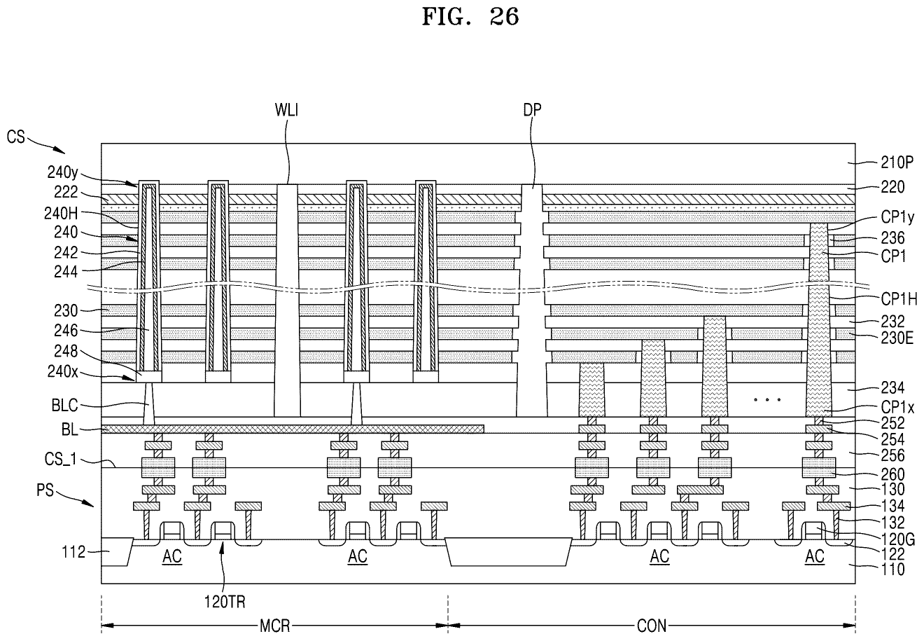

Referring to FIG. 26, the peripheral circuit structure PS may be attached to the cell structure CS. The peripheral circuit structure PS and the cell structure CS may be attached to each other in a metal-oxide hybrid bonding manner through the connection pad 260 and the interlayer insulating films 130 and 256, but are not limited thereto.

Thereafter, the structure in which the peripheral circuit structure PS is attached to the cell structure CS may be inverted so that the substrate 110 faces upward.

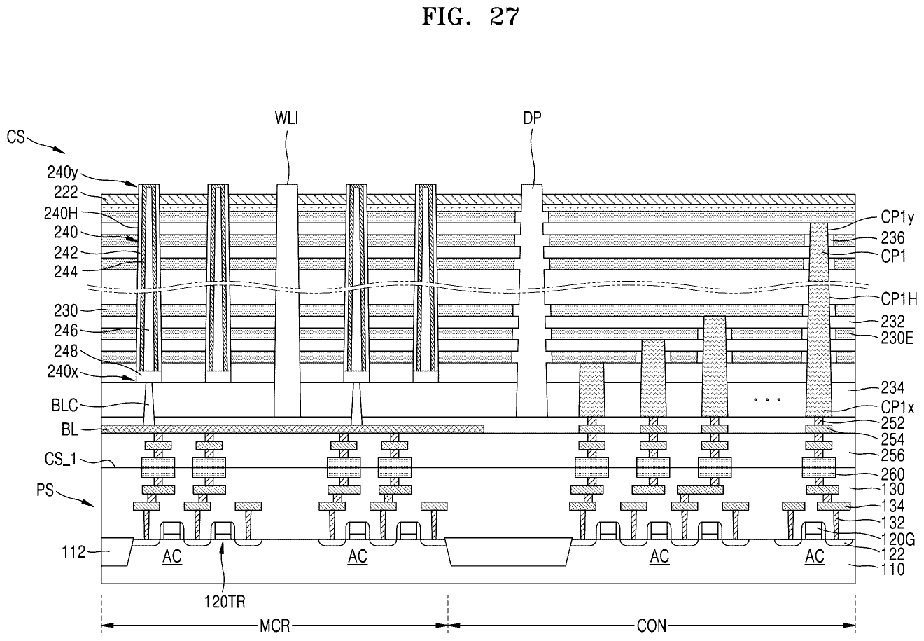

Referring to FIG. 27, the cell substrate 210P (see FIG. 17) may be removed. The cell substrate 210P may be removed by a grinding process and a subsequent etching process and the buffer insulating layer 220 (see FIG. 26) may be exposed.

Thereafter, the buffer insulating layer 220 may also be removed and the top surface of the etch stop layer 222 may be exposed. As the buffer insulating layer 220 is removed, the second end 240y of the channel structure 240 may protrude toward the top surface of the etch stop layer 222.

As the cell substrate 210P and the buffer insulating layer 220 are removed, the upper side of the stack isolation insulating layer WLI and the upper side of the dummy plug DP may also be exposed and protrude above the etch stop layer 222.

Thereafter, the part of the gate insulating layer 242 exposed to the second end 240y of the channel structure 240 may be removed to expose the top surface of the channel layer 244. In some example embodiments, the top surface of the gate insulating layer 242 may be disposed on the same plane as the top surface of the channel layer 244.

In some other example embodiments, in the process of removing the gate insulating layer 242, the gate insulating layer 242 may be removed until the top surface of the etch stop layer 222 is exposed. In some example embodiments, the upper side of the gate insulating layer 242 may be removed so that the gate insulating layer 242 is arranged at a lower level than the top surface of the channel layer 244 and the top surface and the sidewall of the channel layer 244 are partially exposed.

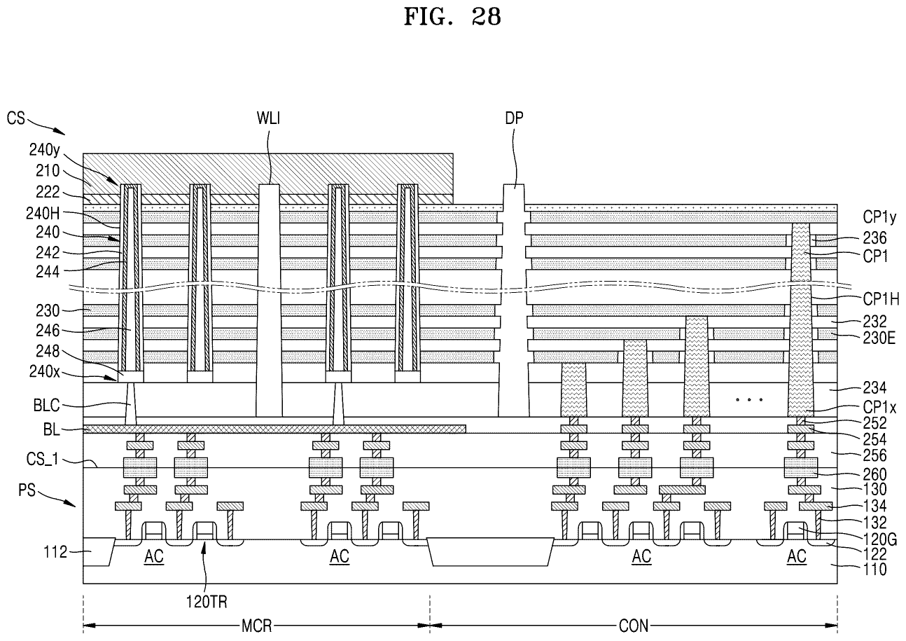

Referring to FIG. 28, the common source layer 210 may be formed in the cell region MCR, the connection region CON, and the peripheral circuit connection region PRC. The common source layer 210 may be formed using polysilicon. For example, the common source layer 210 may be formed using polysilicon doped with an n-type impurity. The common source layer 210 in the cell region MCR may be conformally formed on the exposed top surfaces of the etch stop layer 222 and the channel layer 244.

A part of the common source layer 210 and a part of the etch stop layer 222 arranged in the connection region CON and the peripheral circuit connection region PRC may be removed.

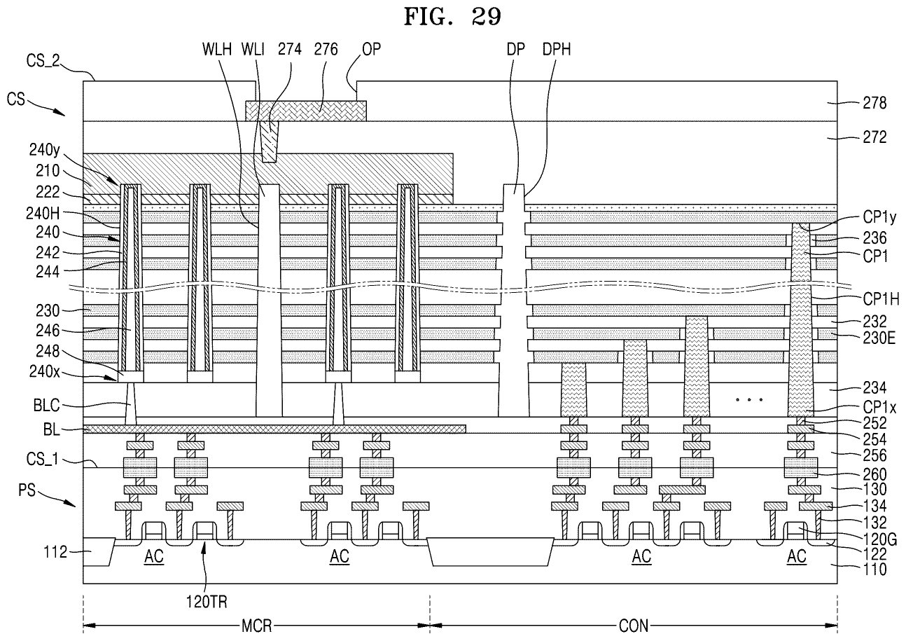

Referring to FIG. 29, the upper insulating layer 272 may be formed on the common source layer 210 and the uppermost mold insulating layer 232 in the cell region MCR, the connection region CON, and the peripheral circuit connection region PRC.

Thereafter, a mask pattern may be formed on the upper insulating layer 272, and a part of the upper insulating layer 272 may be removed using the mask pattern as an etching mask to form a back surface contact hole. The common source contact 274 may be formed in the back surface contact hole, and the back wiring layer 276 electrically connected to the common source contact 274 may be formed on the upper insulating layer 272.

Thereafter, the passivation layer 278 covering the back wiring layer 276 may be formed on the upper insulating layer 272, and the opening OP may be formed in the passivation layer 278 so as to expose the top surface of the back wiring layer 276.

The semiconductor device 100 is completed by performing the above-described processes.

In general, a cell plug may be landed on a stair-shaped pad portion connected to a gate electrode in a connection region. However, there may be a disadvantage in this approach in that the area occupied by the stair-shaped pad portion increases as the number of layers of the gate electrode increases. To address this, instead of forming a stair-shaped pad portion, a stair-free contact structure may be provided that forms a cell plug hole passing through the gate electrode and an insulating liner on the sidewall of the cell plug hole. However, in such a stair-free contact structure, there may occur failure of the insulating spacer that insulates the cell plug and the non-selection electrode.

According to the above-described some example embodiments of the inventive concepts, after forming the dummy plug DP and the gate electrodes 230, the cell plug CP1 and the insulating spacer 236 may be formed, so as to improve the quality of the insulating spacers 236. Therefore, the semiconductor device 100 may have excellent electrical characteristics.

One or more of the elements disclosed above may include or be implemented in processing circuitry such as hardware including logic circuits; a hardware/software combination such as a processor executing software; or a combination thereof. For example, the processing circuitry may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

While the inventive concepts have been particularly shown and described with reference to embodiments thereof, it will be understood that various changes in form and detail may be made therein without departing from the spirit and scope of the following claims.

What is claimed is:

1. A semiconductor device comprising:
a peripheral circuit structure; and
a cell structure on the peripheral circuit structure, the cell structure including a cell region and a connection region,
wherein the cell structure comprises
gate electrodes and mold insulating layers alternately stacked on each other in a vertical direction perpendicular to a top surface of the peripheral circuit structure in the cell region and in the connection region, the gate electrodes comprising a selection electrode and non-selection electrodes,
a channel structure extending in the vertical direction through the gate electrodes in the cell region,
a cell plug contacting the selection electrode, the cell plug being in the connection region and passing through the non-selection electrodes, and the non-selection electrodes being at a lower vertical level than the selection electrode, and
insulating spacers on a side surface of the cell plug, the insulating spacers being spaced apart from each other in the vertical direction,
wherein
the non-selection electrodes and the selection electrode comprise a conductive layer and a coating layer surrounding the conductive layer,
the insulating spacers are between the non-selection electrodes and the side surface of the cell plug,
a first side surface of the conductive layer of the non-selection electrodes faces the side surface of the cell plug,
a first side surface of the coating layer of the non-selection electrodes faces the side surface of the cell plug, and
first side surfaces of the insulating spacers contact the first side surface of the conductive layer of the non-selection electrodes and the first side surface of the coating layer of the non-selection electrodes.

2. The semiconductor device of claim 1, wherein the first side surface of the conductive layer of the non-selection electrodes and the first side surface of the coating layer of the non-selection electrodes are aligned in the vertical direction and are connected to each other.

3. The semiconductor device of claim 1, wherein the first side surface of the conductive layer of the non-selection electrodes is an inwardly concave curved surface.

4. The semiconductor device of claim 1, wherein the first side surface of the conductive layer of the non-selection electrodes and the first side surface of the coating layer of the non-selection electrodes are inclined, and an inclination of the first side surface of the conductive layer of the non-selection electrodes is different from an inclination of the first side surface of the coating layer of the non-selection electrodes.

5. The semiconductor device of claim 1, wherein second side surfaces of the insulating spacers opposite to the first side surfaces of the insulating spacers contact the side surface of the cell plug,
the insulating spacers including a first insulating spacer, and the non-selection electrodes including a first non-selection electrode contacting the first insulating spacer, and
a separation distance between a first side surface of a conductive layer of the first non-selection electrode and the side surface of the cell plug is less than a separation distance between a first side surface of a coating layer of the first non-selection electrode and the side surface of the cell plug.

6. The semiconductor device of claim 1, wherein second side surfaces of the insulating spacers opposite to the first side surfaces of the insulating spacers contact the side surface of the cell plug,
the insulating spacers including a first insulating spacer, and the non-selection electrodes including a first non-selection electrode contacting the first insulating spacer, and
a separation distance between a first side surface of a conductive layer of the first non-selection electrode and the side surface of the cell plug is greater than a separation distance between a side surface of a coating layer of the first non-selection electrode and the side surface of the cell plug.

7. The semiconductor device of claim 1, wherein the cell plug contacts the conductive layer of the selection electrode, and
the coating layer of the selection electrode contacts a part of the side surface of the cell plug.

8. The semiconductor device of claim 1, wherein the insulating spacers include a first insulating spacer, and the non-selection electrodes include a first non-selection electrode contacting the first insulating spacer, and
a first side surface of the first insulating spacer is coplanar with a first side surface of a conductive layer of the first non-selection electrode and a first side surface of a coating layer of the first non-selection electrode.

9. A semiconductor device comprising:
a peripheral circuit structure; and
a cell structure on the peripheral circuit structure, the cell structure comprising a cell region and a connection region,
wherein the cell structure comprises
gate electrodes and mold insulating layers alternately stacked on each other in a vertical direction perpendicular to a top surface of the peripheral circuit structure in the cell region and in the connection region, the gate electrodes comprising a selection electrode and non-selection electrodes,
a channel structure extending in the vertical direction through the gate electrodes in the cell region,
a dummy plug extending in the vertical direction through the gate electrodes in the connection region,
a cell plug contacting the selection electrode, the cell plug being in the connection region and passing through the non-selection electrodes, the non-selection electrodes being at a higher vertical level than the selection electrode, and
insulating spacers on a side surface of the cell plug, the insulating spacers being spaced apart from each other in the vertical direction,
wherein
the non-selection electrodes and the selection electrode comprise a conductive layer and a coating layer surrounding the conductive layer,
the insulating spacers are between the non-selection electrodes and the side surface of the cell plug,
a first side surface of the conductive layer of the non-selection electrodes faces the side surface of the cell plug,
a first side surface of the coating layer of the non-selection electrodes faces the side surface of the cell plug, and
first side surfaces of the insulating spacers directly contact the first side surface of the conductive layer of the non-selection electrodes and the first side surface of the coating layer of the non-selection electrodes.

10. The semiconductor device of claim 9, wherein the dummy plug comprises protrusions protruding in a horizontal direction from a side surface of the dummy plug toward the gate electrodes, the protrusions being spaced apart from each other in the vertical direction.

11. The semiconductor device of claim 10, wherein the conductive layer of the non-selection electrodes includes a second side surface that is opposite the first side surface of the conductive layer of the non-selection electrodes, and the second side surface of the conductive layer faces a corresponding protrusion from among the protrusions of the dummy plug, and
a sidewall of the coating layer of the non-selection electrodes covers the second side surface of the conductive layer of the non-selection electrodes and contacts the corresponding protrusion from among the protrusions of the dummy plug.

12. The semiconductor device of claim 11, wherein the second side surface of the conductive layer of the non-selection electrodes is an outwardly convex curved surface, and
the first side surface of the conductive layer of the non-selection electrodes is an inwardly concave curved surface.

13. The semiconductor device of claim 11, wherein the second side surface of the conductive layer of the non-selection electrodes is covered by the sidewall of the coating layer of the non-selection electrodes, and
the first side surface of the conductive layer of the non-selection electrodes is covered by a corresponding insulating spacer from among the insulating spacers.

14. The semiconductor device of claim 11, wherein side surfaces of the protrusions of the dummy plug are coplanar with an outer surface of the sidewall of the coating layer of the non-selection electrodes, and
the first side surfaces of the insulating spacers are coplanar with the first side surface of the conductive layer of the non-selection electrodes and the first side surface of the coating layer.

15. The semiconductor device of claim 9, wherein a length of the insulating spacers in the vertical direction is greater than a length of the conductive layer of the non-selection electrodes in the vertical direction.

16. The semiconductor device of claim 9, wherein the cell plug is electrically connected to the conductive layer of the selection electrode, and
the coating layer of the selection electrode contacts a part of the side surface of the cell plug.

17. The semiconductor device of claim 9, wherein
a length of the dummy plug in the vertical direction is greater than a length of the cell plug in the vertical direction,
the dummy plug comprises an insulating material, and
the cell plug comprises a conductive material.

18. A semiconductor device comprising:
a peripheral circuit structure; and
a cell structure on the peripheral circuit structure, the cell structure comprising a cell region and a connection region,
wherein the cell structure comprises
gate electrodes and mold insulating layers alternately stacked on each other in a vertical direction perpendicular to a top surface of the peripheral circuit structure in the cell region and in the connection region, the gate electrodes comprising a selection electrode and non-selection electrodes,
a channel structure extending in the vertical direction through the gate electrodes and the mold insulating layers in the cell region,
a cell plug contacting the selection electrode, the cell plug being in the connection region and passing through the non-selection electrodes, and
insulating spacers on a side surface of the cell plug, the insulating spacers being spaced apart from each other in the vertical direction,
wherein
the non-selection electrodes and the selection electrode comprise a conductive layer and a coating layer surrounding the conductive layer,
the insulating spacers are between the non-selection electrodes and the side surface of the cell plug,
a first side surface of the coating layer of the non-selection electrodes and a first side surface of the conductive layer of the non-selection electrodes facing the side surface of the cell plug directly contact first side surfaces of the insulating spacers, and
the first side surface of the conductive layer of the non-selection electrodes and the first side surface the coating layer of the non-selection electrodes are coplanar with the first side surfaces of the insulating spacers.

19. The semiconductor device of claim 18, wherein the side surface of the cell plug contacts the mold insulating layers, the insulating spacers, and the coating layer of the selection electrode.

20. The semiconductor device of claim 18, further comprising a dummy plug extending in the vertical direction through the gate electrodes in the connection region,
wherein the dummy plug comprises protrusions protruding in a horizontal direction toward the gate electrodes, the protrusions being on a side surface of the dummy plug and spaced apart from each other in the vertical direction, and
a second side surface of the conductive layer of the non-selection electrodes faces the protrusions of the dummy plug, the second side surface of the conductive layer of the non-selection electrodes is spaced apart from the dummy plug, and a sidewall of the coating layer is between the second side surface of the conductive layer of the non-selection electrodes and the dummy plug.
